(19) United States
(12) Patent Application Publication
(10) Pub. No.: US 2024/0206317 A1
(43) Pub. Date: Jun. 20, 2024

(54) ORGANIC METAL COMPLEX AND ORGANIC LIGHT EMITTING ELEMENT

(71) Applicant: CANON KABUSHIKI KAISHA, Tokyo (JP)

(72) Inventors: KENJI YAMADA, Kanagawa (JP); ISAO KAWATA, Kanagawa (JP); KATSUYUKI HOTTA, Kanagawa (JP); YUKA KIMURA, Fukui (JP)

(21) Appl. No.: 18/520,315

(22) Filed: Nov. 27, 2023

(30) Foreign Application Priority Data
Nov. 28, 2022 (JP) 2022-189150
Jul. 13, 2023 (JP) 2023-114990

(51) Int. Cl. H10K 85/30; C07F 15/00; C09K 11/06; G03G 15/04

(52) U.S. Cl. CPC H10K 85/342; C07F 15/0086; C09K 11/06; G03G 15/04036; C09K 2211/1029; C09K 2211/185; H10K 50/12

(57) ABSTRACT

An organic metal complex exhibits high oscillator strength and high molecular stability since the organic metal complex contains a ligand in which a benzoisoquinoline ring and a benzene ring are bonded together via a five-membered ring structure.

### BACKGROUND OF THE INVENTION

### Field of the Invention

The present disclosure relates to an organic metal complex that exhibits high light emitting efficiency, an organic light emitting element including the same and having a long element lifetime, and a device and equipment that include the organic light emitting element.

### Description of the Related Art

An organic light emitting element (also referred to as an organic electroluminescence element or an organic EL element) is an electronic element that includes a first electrode, a second electrode, and an organic compound layer disposed between these electrodes. By injecting electrons and holes from the pair of electrodes, excitons of a light emitting organic compound in the organic compound layer are generated, and the organic light emitting element emits light as the excitons return to the ground state. Recent advancement in organic light emitting elements has been remarkable, enabling low drive voltage, a wide variety of emission wavelengths, high-speed responsivity, and thickness and weight reduction of light emitting devices.

Presently, as an attempt to improve the light emitting efficiency of organic light emitting elements, the use of phosphorescence emission has been proposed. An organic light emitting element that uses phosphorescence emission is theoretically expected to achieve light emitting efficiency about four times higher than that of the fluorescent emission. Thus, to date, creation of phosphorescence-emitting organic metal complexes has been actively pursued. Iridium complexes are a representative example of phosphorescence emitting organic metal complexes, and the light emitting efficiency thereof is required to improve further in order to increase the luminance and decrease the power consumption of the organic light emitting elements. Furthermore, further improvements are required to address changes over time that occur due to long-term use and the lifetime that resists deterioration.

Japanese Patent Laid-Open No. 2009-114137 (PTL 1) discloses a compound A below that serves as a phosphorescence emitting material having high light emitting efficiency, and Japanese Patent Laid-Open No. 2020-164863 (PTL 2) discloses a compound B below that serves as a compound that gives a low drive voltage, high efficiency organic light emitting element.

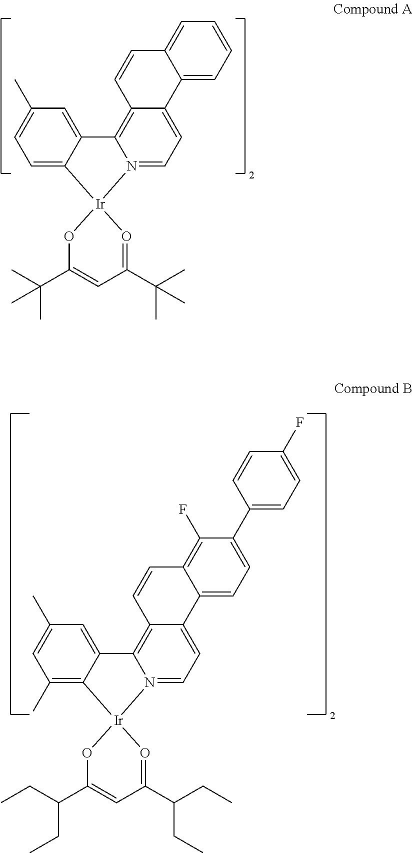

The compound A disclosed in PTL 1 is an organic metal complex that has a benzoisoquinoline skeleton in a main ligand and has high light emitting efficiency; however, higher light emitting efficiency has been required. The compound B disclosed in PTL 2 is also a compound in which the main ligand has a moiety including a benzoisoquinoline skeleton bonded to a phenyl group, and although the efficiency thereof is high, the lifetime has been insufficient.

### SUMMARY OF THE INVENTION

The present disclosure has addressed the problems described above and provides an organic metal complex that achieves both high light emitting efficiency and long lifetime.

The present disclosure provides an organic metal complex represented by formula (1) below:

MLₚL¹ₘL²ₙ (1)

In formula (1), L, L¹, and L² represent different ligands. M is Ir, Rh, Pt, or Pd.
p is an integer of 1 to 3, m is an integer of 0 to 2, n is an integer of 0 to 2, when M is Ir or Rh, p+m +n=3, and when M is Pt or Pd, p+m+n=2.
MLₚ is represented by formula (2) below.

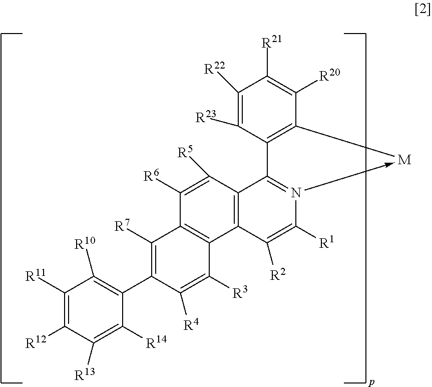

In formula (2), R¹ to R⁷, R¹⁰ to R¹⁴,
R²⁰ to R²³ are each independently selected from the group consisting of a hydrogen atom, a deuterium atom, a halogen atom, a substituted or unsubstituted alkyl group, a substituted or unsubstituted alkoxy group, a substituted or unsubstituted aryl group, a substituted or unsubstituted aryloxy group, a substituted or unsubstituted heterocyclic group, a substituted or unsubstituted aralkyl group, a substituted or unsubstituted amino group, a silyl group, and a cyano group. R⁴ and R¹⁴ and/or R⁷ and R¹⁰ are bonded together to form a five-membered ring structure.

Any of R¹ to R⁷, R¹⁰ to R¹⁴, and R²⁰ to R²³ may form a ring structure by bonding with an adjacent substituent.

ML¹ₘ and ML²ₙ are respectively represented by formulae (3) and (4) below:

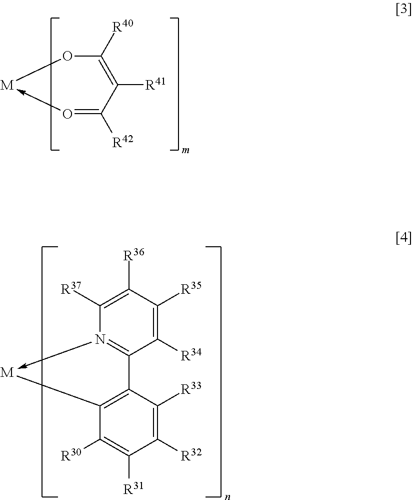

In formulae (3) and (4), R³⁰ to R³⁷ and R⁴⁰ to R⁴² are each independently selected from the group consisting of a hydrogen atom, a deuterium atom, a halogen atom, a substituted or unsubstituted alkyl group, a substituted or unsubstituted alkoxy group, a substituted or unsubstituted aralkyl group, a substituted or unsubstituted amino group, a substituted or unsubstituted aryl group, and a substituted or unsubstituted heterocyclic group. Further features of the present disclosure will become apparent from the following description of exemplary embodiments with reference to the attached drawings.

### BRIEF DESCRIPTION OF THE DRAWINGS

FIG. 1A is a schematic cross sectional view illustrating one example of a pixel of a display device according to an embodiment of the present disclosure; and FIG. 1B is a schematic cross sectional view illustrating one example of a display device that uses an organic light emitting element according to one embodiment of the present disclosure.

FIG. 2 is a schematic diagram illustrating one example of a display device according to one embodiment of the present disclosure.

FIG. 3A is a schematic diagram illustrating one example of an imaging device according to one embodiment of the present disclosure; and FIG. 3B is a schematic diagram illustrating one example of electronic equipment according to an embodiment the present disclosure.

FIG. 4A is a schematic diagram illustrating one example of a display apparatus according to one embodiment of the present disclosure; and FIG. 4B is a schematic diagram illustrating one example of a bendable display apparatus.

FIG. 5A is a schematic diagram illustrating one example of a lighting apparatus according to an embodiment of the present disclosure; and FIG. 5B is a schematic diagram illustrating one example of an automobile equipped with a car lighting unit according to an embodiment of the present disclosure.

FIG. 6A is a schematic diagram illustrating one example of a wearable device according to one embodiment of the present disclosure; and FIG. 6B is a schematic diagram illustrating one example of a wearable device according to one embodiment of the present disclosure and equipped with an imaging device.

### DESCRIPTION OF THE EMBODIMENTS

An organic metal complex according to one embodiment of the present disclosure is represented by general formula (1) below:

MLₚL¹ₘL²ₙ (1)

In general formula (1), L, L¹, and L² represent different ligands. M is Ir, Rh, Pt, or Pd.

p is an integer of 1 to 3, m is an integer of 0 to 2, n is an integer of 0 to 2, when M is Ir or Rh, p+m+n=3, and when M is Pt or Pd, p+m+n=2.

MLₚ is represented by general formula (2) below.

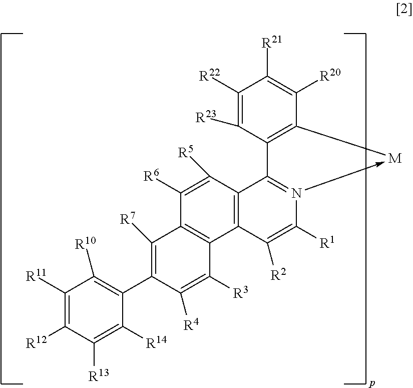

In general formula (2), R¹ to R⁷, R¹⁰ to R¹⁴, R²⁰ to R²³ are each independently selected from the group consisting of a hydrogen atom, a deuterium atom, a halogen atom, a substituted or unsubstituted alkyl group, a substituted or unsubstituted alkoxy group, a substituted or unsubstituted aryl group, a substituted or unsubstituted aryloxy group, a substituted or unsubstituted heterocyclic group, a substituted or unsubstituted aralkyl group, a substituted or unsubstituted amino group, a silyl group, and a cyano group. Here, R⁴ and R¹⁴ and/or R⁷ and R¹⁰ are bonded together to form a five-membered ring structure.

Any of R¹ to R⁷, R¹⁰ to R¹⁴, and R²⁰ to R²³ may form a ring structure by bonding with an adjacent substituent.

ML¹ₘ and ML²ₙ are respectively represented by general formulae (3) and (4) below. M may be Ir.

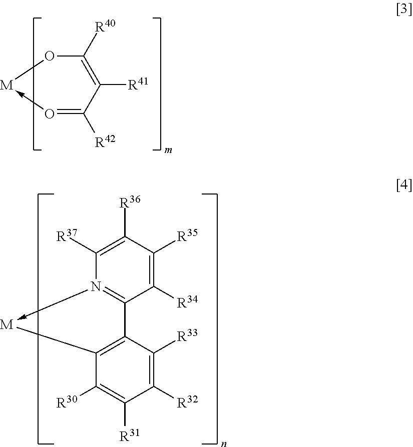

In general formulae (3) and (4), R³⁰ to R³⁷ and R⁴⁰ to R⁴² are each independently selected from the group consisting of a hydrogen atom, a deuterium atom, a halogen atom, a substituted or unsubstituted alkyl group, a substituted or unsubstituted alkoxy group, a substituted or unsubstituted aralkyl group, a substituted or unsubstituted amino group, a substituted or unsubstituted aryl group, and a substituted or unsubstituted heterocyclic group.

In general formula (3), R⁴⁰ and R⁴² may each be an alkyl having 1 to 8 carbon atoms, specifically, a methyl group, an ethyl group, an isopropyl group, a t-butyl group, or —CH(C₂H₅)₂.

When the substituents R⁴⁰ to R⁴² are bulky, the heat resistance and the sublimability of the organic metal complex are sometimes improved. In particular, the combination of R⁴⁰, R⁴¹, and R⁴² can be the combination of an isopropyl group, a hydrogen atom, and an isopropyl group, the combination of —CH(C₂H₅)₂, a hydrogen atom, and —CH(C₂H₅)₂, the combination of a t-butyl group, a hydrogen atom, and a t-butyl group, or the combination of an ethyl group, a hydrogen atom, and a methyl group.

ML₁ represented by general formula (2) may be represented by general formula (5), (6), or (7) below. M may be Ir. When M is Ir, general formulae (5), (6), and (7) below are general formulae (5′), (6′), and (7′) below.

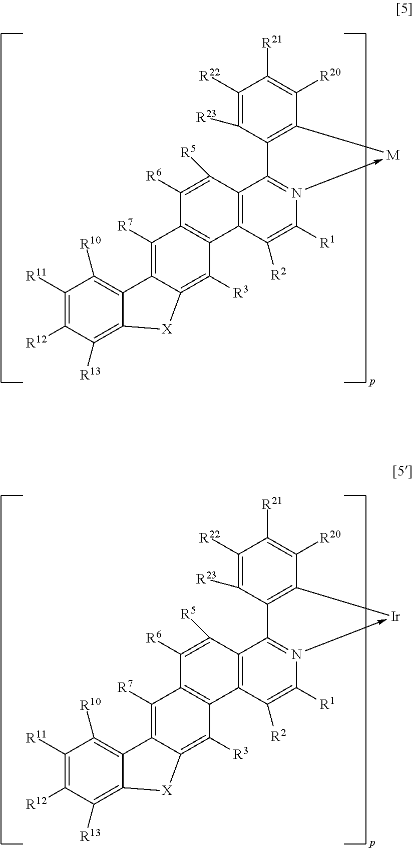

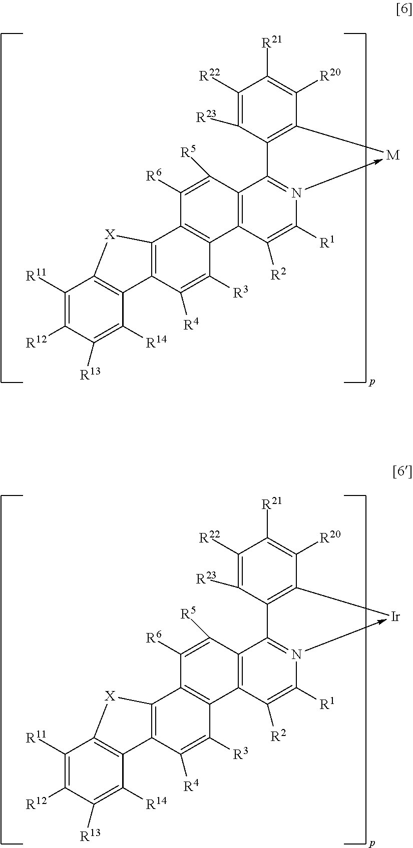

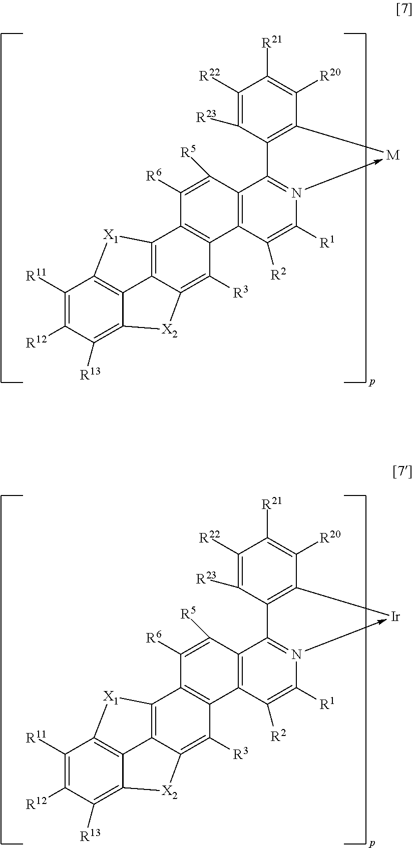

General formula (5) is the same as general formula (2) with R⁴ and R¹⁴ bonded together via X to form a five-membered ring structure, and general formula (6) is the same as general formula (2) with R⁷ and R¹⁰ bonded together via X to form a five-membered ring structure. General formula (7) is the same as general formula (2) with R⁴ and R¹⁴ bonded together via X₁ to form a five-membered ring structure and with R⁷ and R¹⁰ bonded together via X₂ to form a five-membered ring structure.

R¹ to R³, R⁵ to R⁷, R¹⁰ to R¹³, and R²⁰ to R²³ in general formula (5), R¹ to R⁶, R¹¹ to R¹⁴, and R²⁰ to R²³ in general formula (6), and R¹ to R³, R⁵, R⁶, R¹¹ to R¹³, and R²⁰ to R²³ in general formula (7) are the same as those in general formula (2). In other words, these substituents are each independently selected from a hydrogen atom, a deuterium atom, a halogen atom, a substituted or unsubstituted alkyl group, a substituted or unsubstituted alkoxy group, a substituted or unsubstituted aryl group, a substituted or unsubstituted aryloxy group, a substituted or unsubstituted heterocyclic group, a substituted or unsubstituted aralkyl group, a substituted or unsubstituted amino group, a silyl group, and a cyano group.

In general formulae (5), (6), and (7), X, X₁, and X₂ are each independently selected from CRR′, C═O, SiRR′, O, S, SO₂, and NR where R and R′ are each independently selected from the group consisting of a substituted or unsubstituted alkyl group, a substituted or unsubstituted aryl group, and a halogen atom. Here, in general formula (7), X₁ and X₂ may be the same or different.

The alkyl group, alkoxy group, halogen atom, amino group, aryl group, aryloxy group, heterocyclic group, aralkyl group, and amino group described in relation to general formulae (2) to (7) will now be specifically described.

The alkyl group is an alkyl group preferably having 1 to 10 carbon atoms, more preferably 1 to 8 carbon atoms, and yet more preferably 1 to 4 carbon atoms. Specific examples thereof include, but are not limited to, a methyl group, an ethyl group, a normal propyl group, an isopropyl group, a normal butyl group, a tert-butyl group, a sec-butyl group, an ethylhexyl group, an octyl group, a cyclopentyl group, a cyclohexyl group, a 1-adamantyl group, and a 2-adamantyl group.

The alkoxy group is an alkoxy group preferably having 1 to 10 carbon atoms, more preferably 1 to 6 carbon atoms, and yet more preferably 1 to 4 carbon atoms. Specific examples thereof include, but are not limited to, a methoxy group, an ethoxy group, a propoxy group, a 2-ethyl-hexyloxy group, and a benzyloxy group.

Examples of the halogen atom include, but are not limited to, fluorine, chlorine, bromine, and iodine. A fluorine atom is preferable among halogen atoms.

The amino group may be unsubstituted or substituted with any one of an alkyl group, an aryl group, and an amino group. The alkyl group, aryl group, and amino group serving as substituents may each have a halogen atom as a substituent, and the aryl group and amino group may have an alkyl group as a substituent. In the amino group, substituent alkyl groups may bond together to form a ring. Specific examples thereof include, but are not limited to, a N-methylamino group, a N-ethylamino group, a N,N-dimethylamino group, a N,N-diethylamino group, a N-methyl-N-ethylamino group, a N-benzylamino group, a N-methyl-N-benzylamino group, a N,N-dibenzylamino group, an anilino group, a N,N-diphenylamino group, a N,N-dinaphthylamino group, a N,N-difluorenylamino group, a N-phenyl-N-tolylamino group, a N,N-ditolylamino group, a N-methyl-N-phenylamino group, a N,N-dianisorylamino group, a N-mesityl-N-phenylamino group, a N,N-dimesitylamino group, a N-phenyl-N -(4-tert-butylphenyl)amino group, a N-phenyl-N-(4-trifluoromethylphenyl)amino group, and a N-piperidyl group.

The aryl group may be an aryl group having 6 to 18 carbon atoms, and specific examples thereof include a phenyl group, a naphthyl group, an indenyl group, a biphenyl group, a terphenyl group, a fluorenyl group, a phenanthryl group, and a triphenylenyl group.

The heterocyclic group may be a heterocyclic group having 3 to 15 carbon atoms, and may have N, S, and O as the heteroatoms. Specific examples thereof include, but are not limited to, a pyridyl group, a pyrazyl group, a pyrimidyl group, a triazyl group, an imidazolyl group, an oxazolyl group, an oxadiazolyl group, a thiazolyl group, a thiadiazolyl group, a carbazolyl group, an acridinyl group, a phenanthrolyl group, a furanyl group, a thiophenyl group, a dibenzofuranyl group, and a dibenzothiophenyl group.

Examples of the aryloxy group include, but are not limited to, a phenoxy group and a thienyloxy group.

Examples of the silyl group include, but are not limited to, a trimethylsilyl group and a triphenylsilyl group.

The alkyl group, alkoxy group, amino group, aryl group, heterocyclic group, and aryloxy group described above may each have a deuterium atom as a substituent. Examples of the alkyl group having a deuterium atom as a substituent include, but are not limited to, —CD₃, —CD₂CH₃, and —CD₂CD₃.

The alkyl group, alkoxy group, amino group, aryl group, heterocyclic group, and aryloxy group described above may each have a halogen atom as a substituent, and the halogen atom is, for example, fluorine, chlorine, bromine or iodine, and may be a fluorine atom. In particular, the alkyl group can have a fluorine atom, and specific examples thereof include a methyl trifluoride group (—CF₃) and a pentafluoroethyl group (—C₂F₅).

The amino group, aryl group, heterocyclic group, and aryloxy group described above may each have an alkyl group as a substituent, and this alkyl group may have 1 to 10 carbon atoms. Specific examples thereof include a methyl group, an ethyl group, a normal propyl group, an isopropyl group, a normal butyl group, and a tert-butyl group.

The alkyl group, alkoxy group, aryl group, aryloxy group, heterocyclic group, aralkyl group, and amino group described above may each have an aryl group, a heterocyclic group, an amino group, an aralkyl group, an alkoxy group, an aryloxy group, a cyano group, or the like as a substituent. The aryl group may have 6 to 12 carbon atoms, and specific examples thereof include a phenyl group, a biphenyl group, and a naphthyl group. The heterocyclic group may have 3 to 9 carbon atoms, and examples of the heteroatom include nitrogen, sulfur, and oxygen. Specific examples thereof include a pyridyl group and a pyrrolyl group. The amino group may be substituted with an alkyl group or an aryl group, and the alkyl groups may bond together to form a ring. Specific examples thereof include a dimethylamino group, a diethylamino group, a dibenzylamino group, a diphenylamino group, and a ditolylamino group. An example of the aralkyl group is a benzyl group, examples of the alkoxy group include a methoxy group, an ethoxy group, and a propoxy group, and an example of the aryloxy group is a phenoxy group.

The organic metal complex according to this embodiment can provide an organic EL material and an organic light emitting element that have high light emitting efficiency and long lifetime. Here, in order to increase the efficiency of the emission quantum yield of a phosphorescence emitting material such as iridium complexes, it is effective to increase the transition dipole moment in the excited state of the complex and improve the oscillator strength. According to an iridium complex of this embodiment in which the main ligand has a conjugated structure formed by a benzoisoquinoline (BIQ) ring bonded with another aromatic ring via a five-membered ring structure, the conjugation is expanded in such a direction that the center of gravity of the conjugate plane is farther away from the metal atom. Thus, in an excited state of the complex, the electron moving distance from the metal atom to the ligand is extended, the transition dipole moment is increased, and thus the oscillator strength can be improved. As a result, the organic metal complex exhibits high light emitting efficiency.

Here, the oscillator strength of an organic metal complex can be determined by calculating the ground state and the excited state of molecules by using electronic structure calculation software, Gaussian 09 * Revision C.01, and bundled software calculating spin orbit coupling. During this process, the density functional theory is employed as the ground state calculation method, and the time-dependent density functional theory is employed as the excited state calculation method. For both calculations, B3PW91 was used as the functional. LANL2DZ was used as the base function.

Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr. J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc. Wallingford CT, 2010.

The compound A below disclosed in PTL 1 and example compounds of the present embodiment described below were calculated for their oscillator strength. The calculation results are indicated in Table 1.

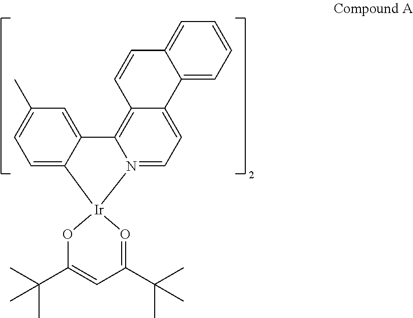

TABLE 1

| Compound Name | Oscillator strength |
|---|---|
| Compound A (PTL 1) | 1.11 × 10⁻³ |
| Example Compound A-1 | 1.65 × 10⁻³ |
| Example Compound A-4 | 1.60 × 10⁻³ |
| Example Compound A-9 | 1.94 × 10⁻³ |
| Example Compound A-10 | 2.05 × 10⁻³ |
| Example Compound A-13 | 2.16 × 10⁻³ |
| Example Compound A-16 | 2.01 × 10⁻³ |
| Example Compound A-17 | 1.46 × 10⁻³ |
| Example Compound A-19 | 2.20 × 10⁻³ |
| Example Compound A-21 | 2.46 × 10⁻³ |
| Example Compound A-22 | 1.66 × 10⁻³ |
| Example Compound A-24 | 2.18 × 10⁻³ |
| Example Compound A-43 | 1.96 × 10⁻³ |
| Example Compound B-2 | 1.73 × 10⁻³ |
| Example Compound B-5 | 1.91 × 10⁻³ |
| Example Compound B-6 | 1.54 × 10⁻³ |
| Example Compound B-11 | 1.60 × 10⁻³ |
| Example Compound B-15 | 2.26 × 10⁻³ |

As indicated in Table 1, the oscillator strengths of the example compounds of the present embodiment were about 1.3 times to 2.2 times larger than the oscillator strength of the compound A disclosed in PTL 1. This shows that the iridium complexes in which the main ligand is a conjugated structure included in the example compounds of the present embodiment and formed by a BIQ ring and another aromatic ring bonded together via a five-membered ring structure increase the transition dipole moment most, and contribute to increasing the oscillator strength and associated improvement in the light emitting efficiency.

It has been found that, in particular, as seen in the example compounds A-9, A-10, A-13, A-16, A-19, A-21, A-24, and A-43, for example, introduction of an electron-withdrawing group into a substituent (R¹⁰ to R¹⁴ in general formula (2)) of an aromatic ring bonded to the BIQ ring via a five-membered ring structure can realize a larger oscillator strength. This electron-withdrawing property can be expressed by a Hammett constant, and providing an electron-withdrawing substituent having a para-Hammett constant op larger than or equal to 0.2 can improve the light emitting efficiency of an organic light emitting element. In particular, —CF₃, —CN, —COCH₃, or —F is preferable, and —CF₃ is particularly preferable.

Next, the stability and the lifetime of the iridium complexes according to the present embodiment are described.

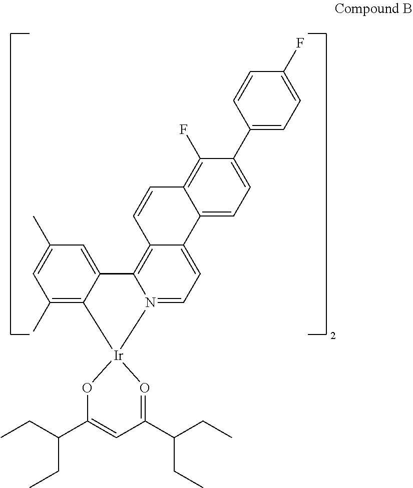

The compound B disclosed in PTL 2 above has a fluorine-substituted benzene ring bonded to a BIQ ring only via a single bond, and thus the compound is vulnerable and offers a short light emitting element lifetime. In the present embodiment, it has been found that the molecular stability improves prominently when the bonding mode between the BIQ ring and the benzene ring is a cyclic, five-membered ring structure that has not only a single bond but also an additional crosslinking structure. Whereas the fluorine-substituted benzene ring in the compound B freely rotates about the axis of the single bond with respect to the plane of the BIQ ring, the BIQ ring and the benzene ring in the compound of the present embodiment are bonded together via a five-membered ring structure, and thus the bond between the two is strong and rigid, providing steric stability. Furthermore, formation of the five-membered ring structure stably immobilizes the π planes of the BIQ ring and the benzene ring and enhances delocalization of electrons. Thus, the molecular stability is improved also from the electronic viewpoint. Accordingly, the bonding mode between the BIQ ring and the benzene ring can be bonding via a five-membered ring structure, which provides high planarity and rigidity of the two rings, rather than a single bond or other bonding structures such as a six-membered ring or an eight-membered ring.

Specific structural formulae of the organic metal complex of the present embodiment are described below as examples. However, the organic metal complex of the present embodiment is not limited to these.

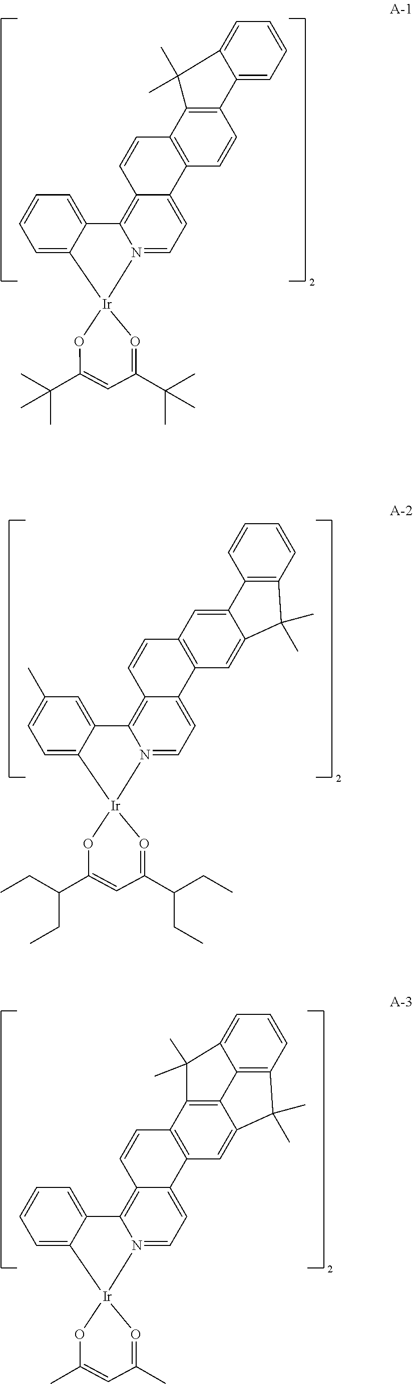

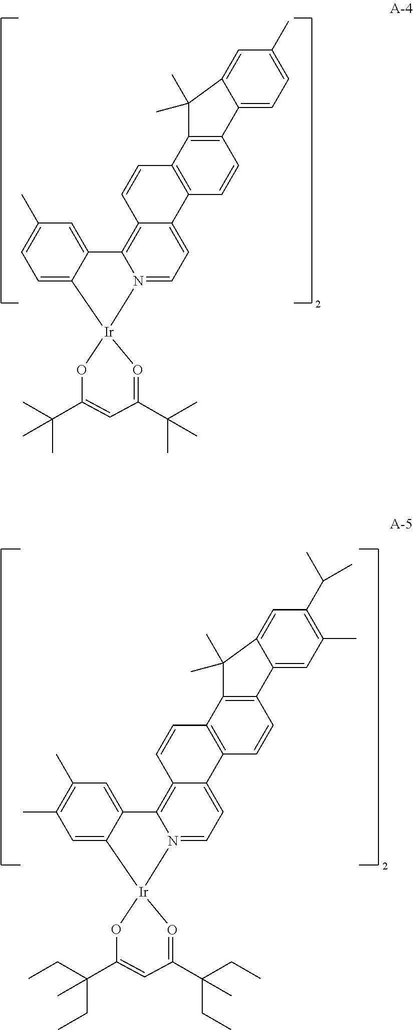

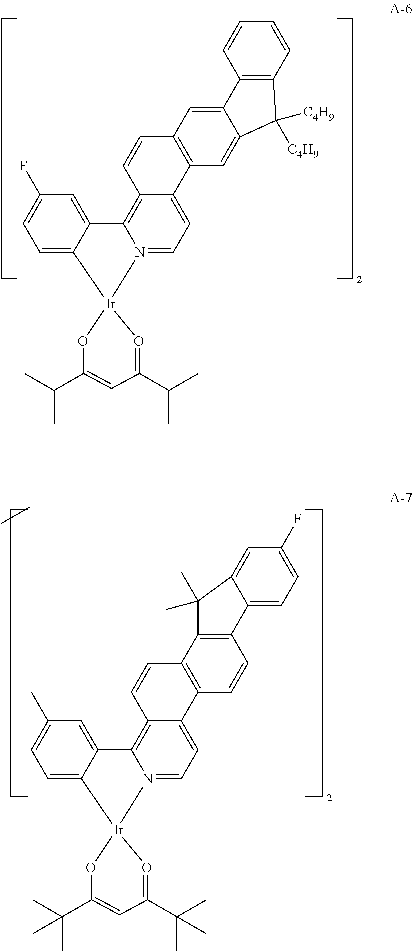

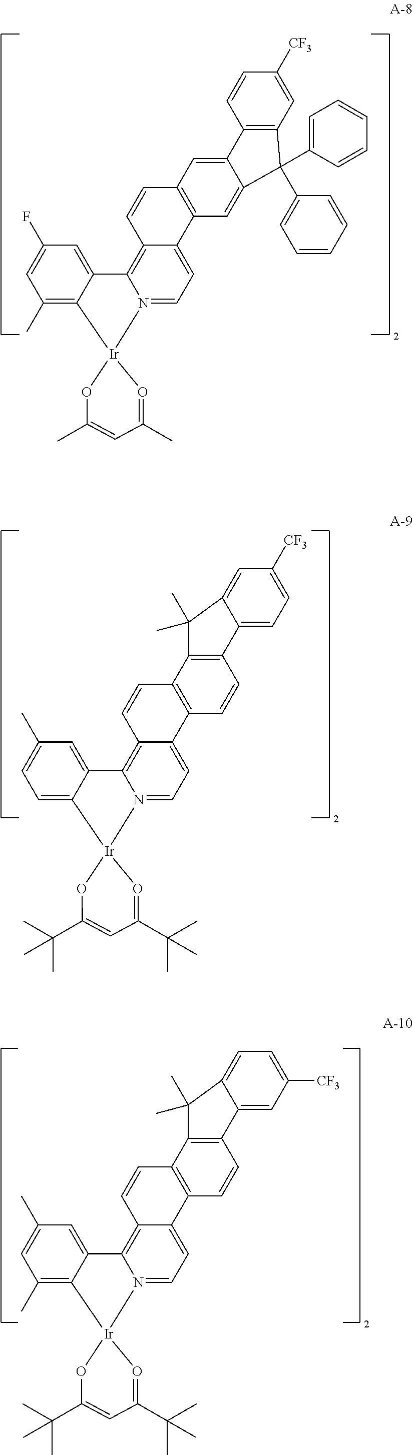

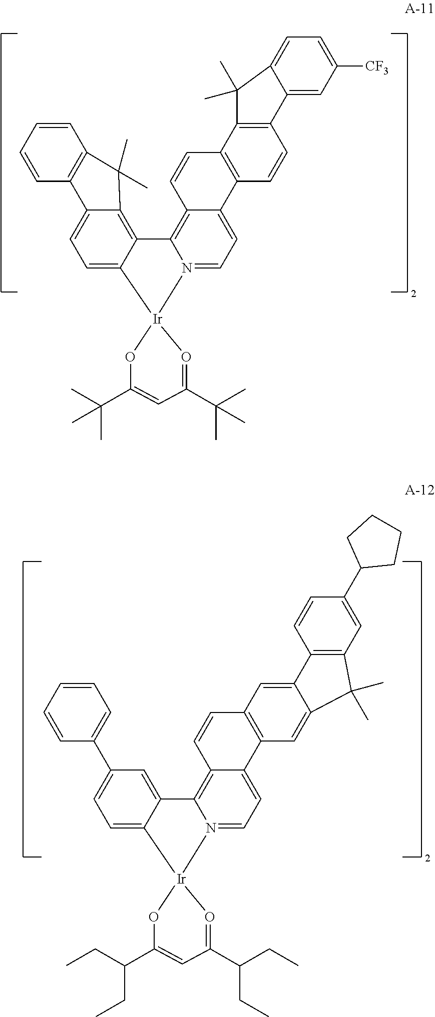

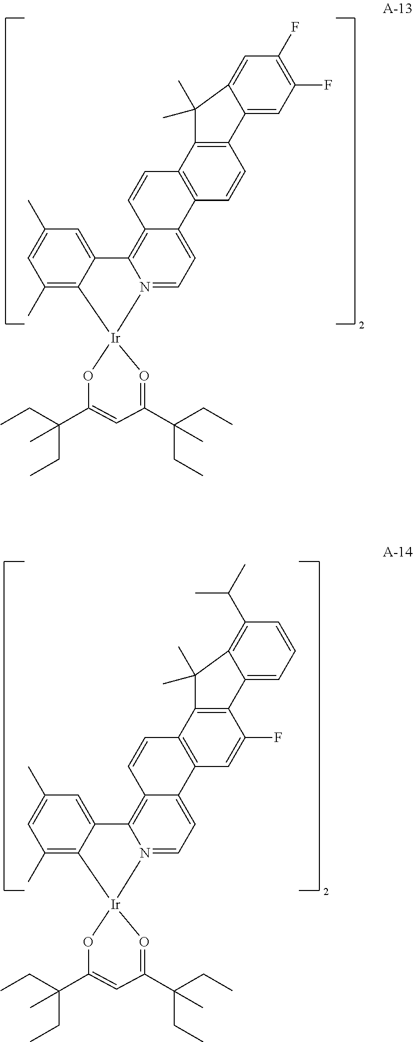

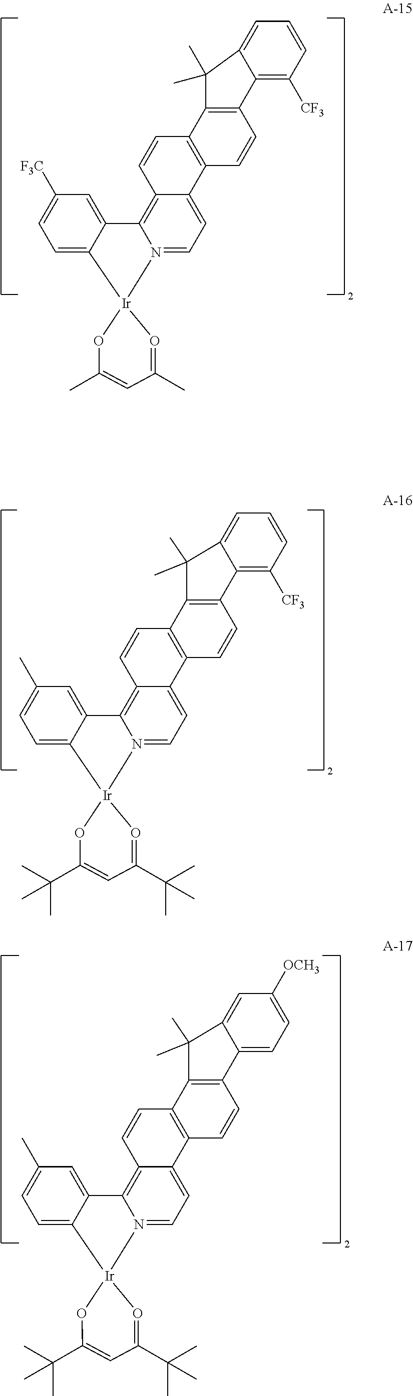

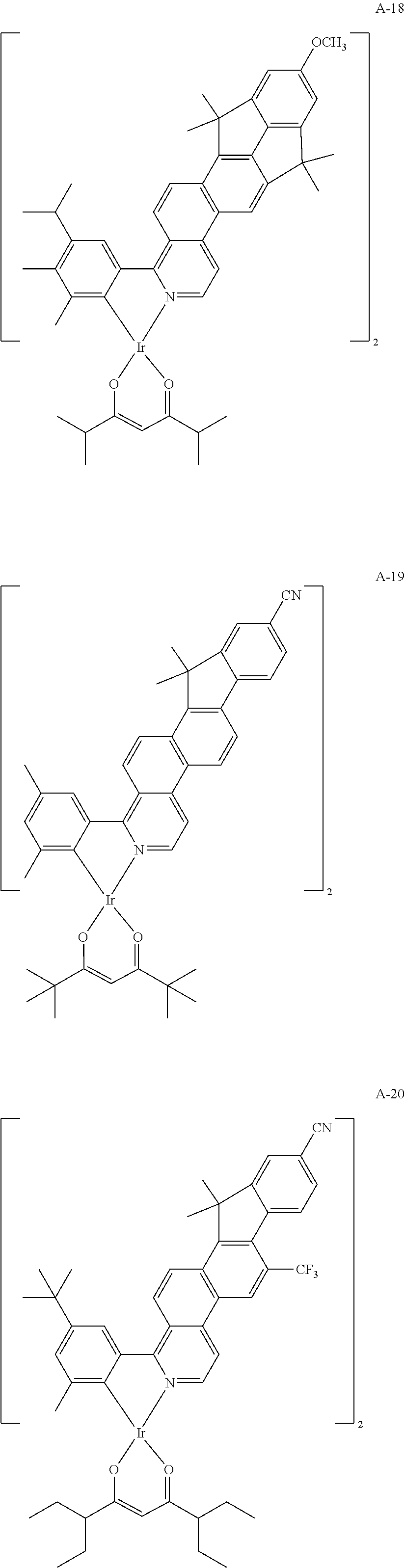

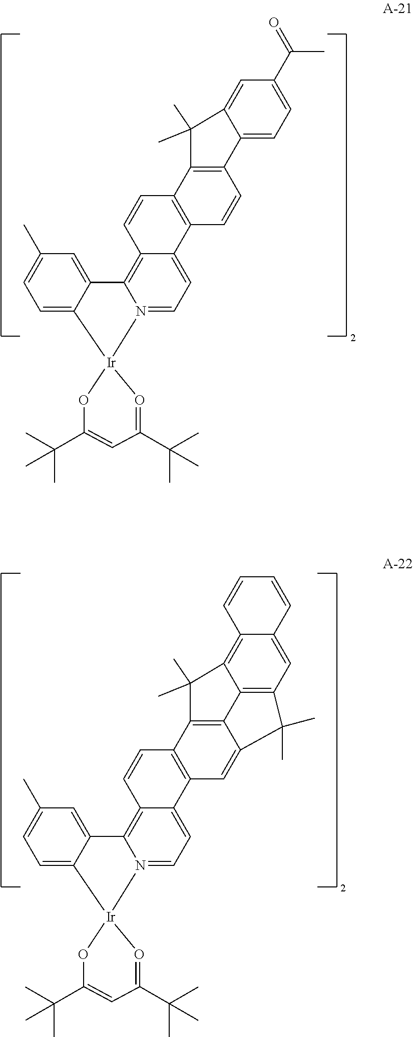

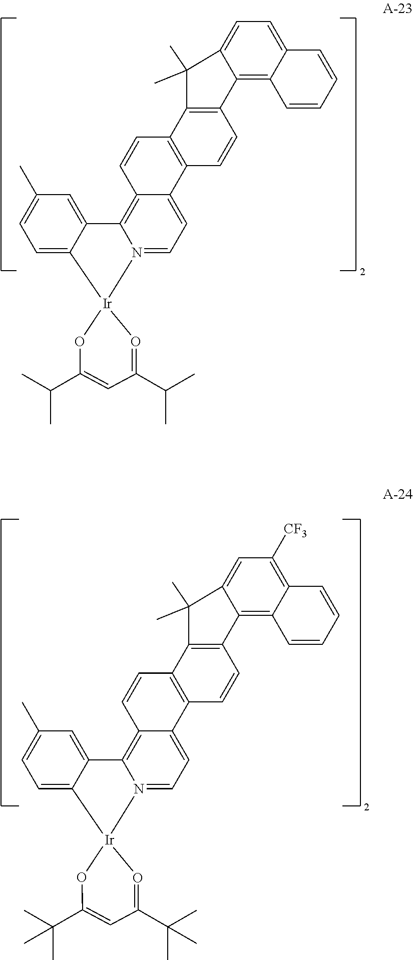

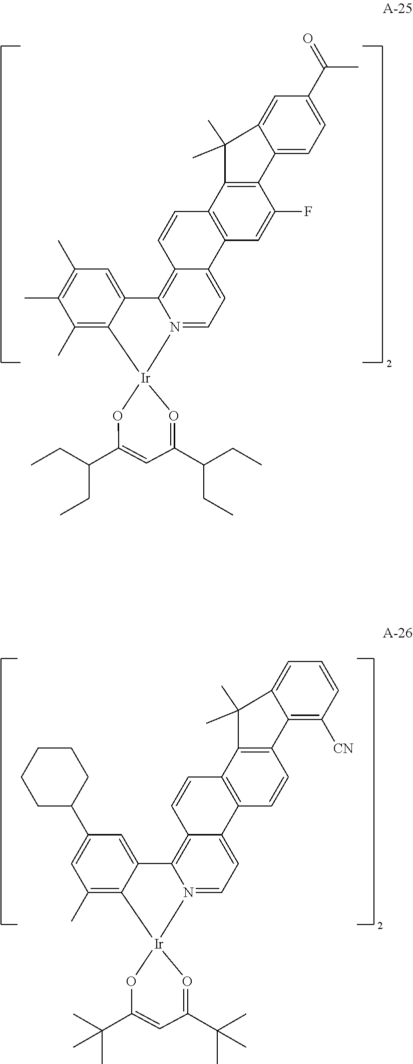

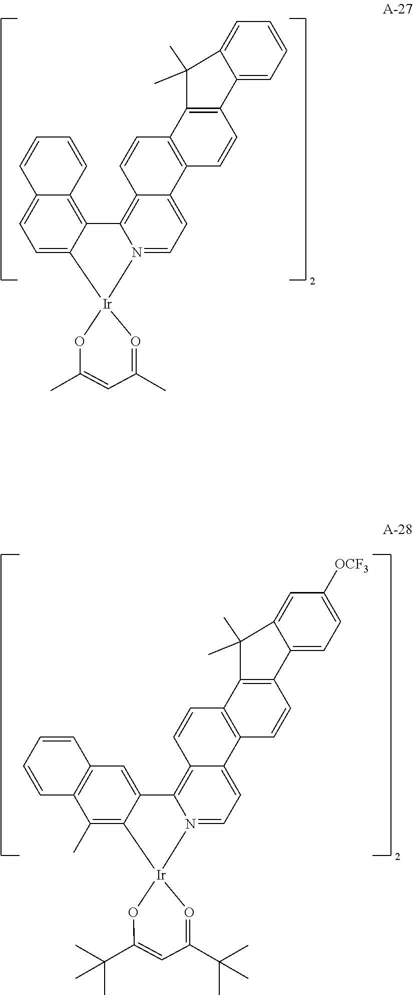

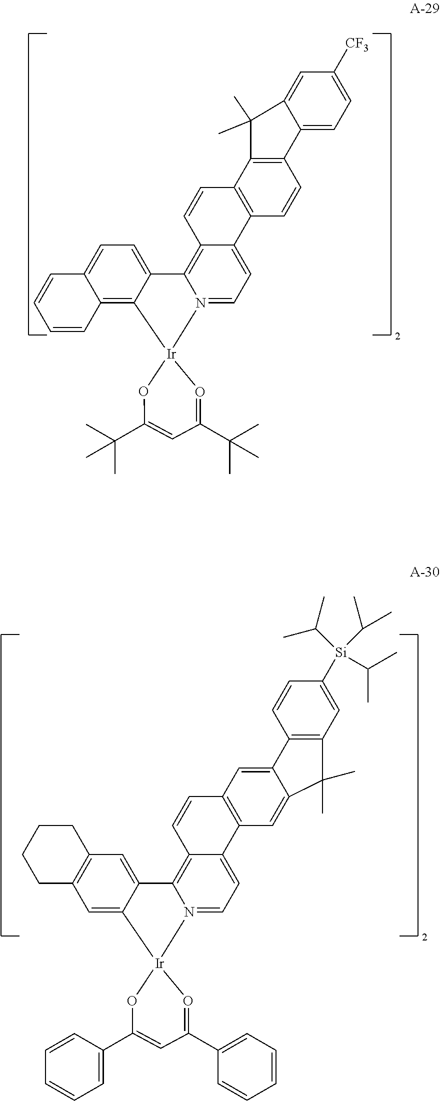

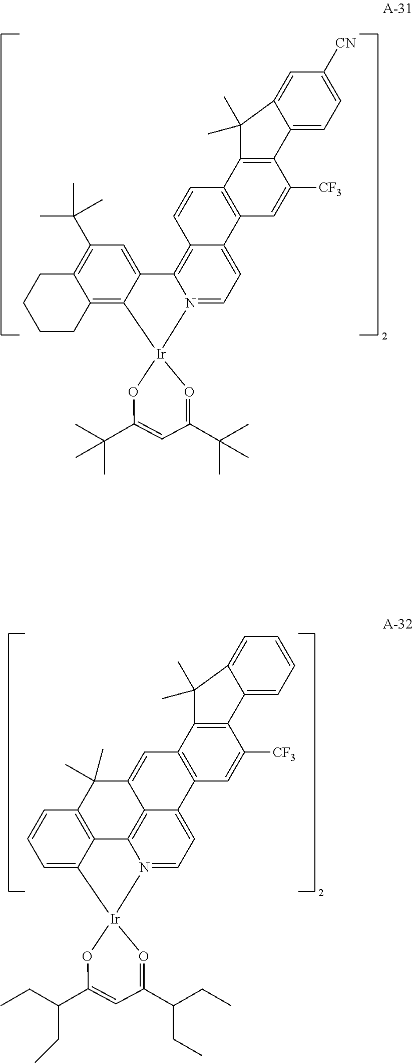

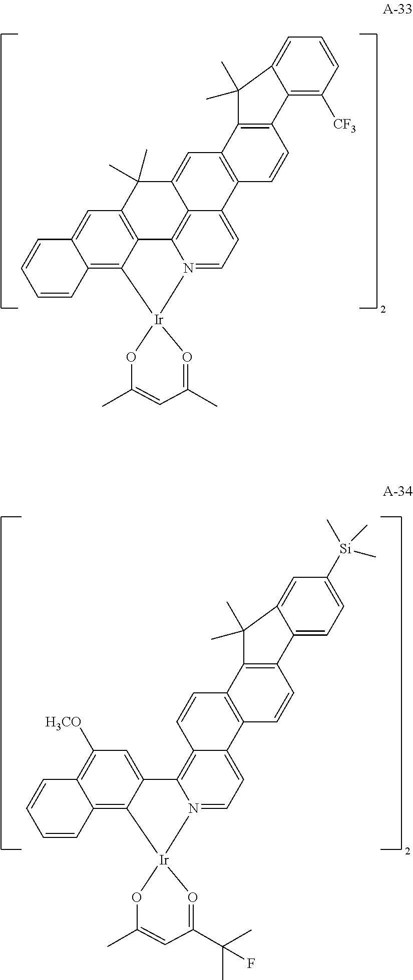

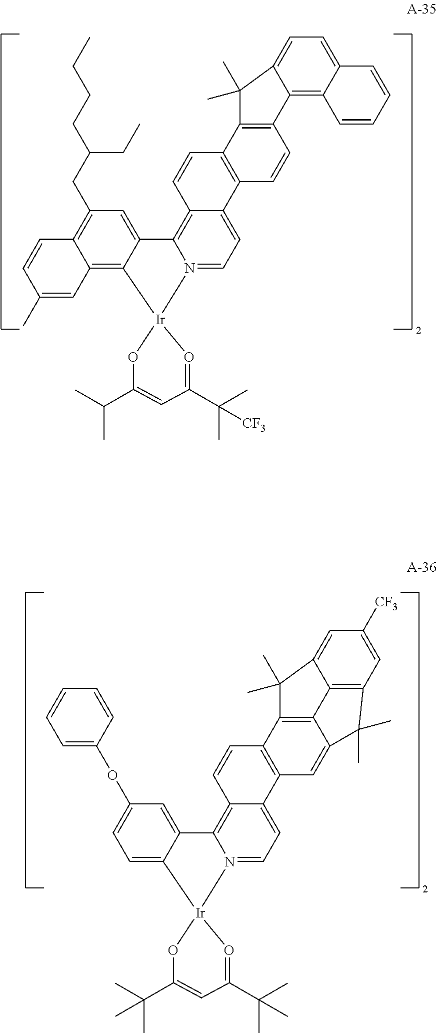

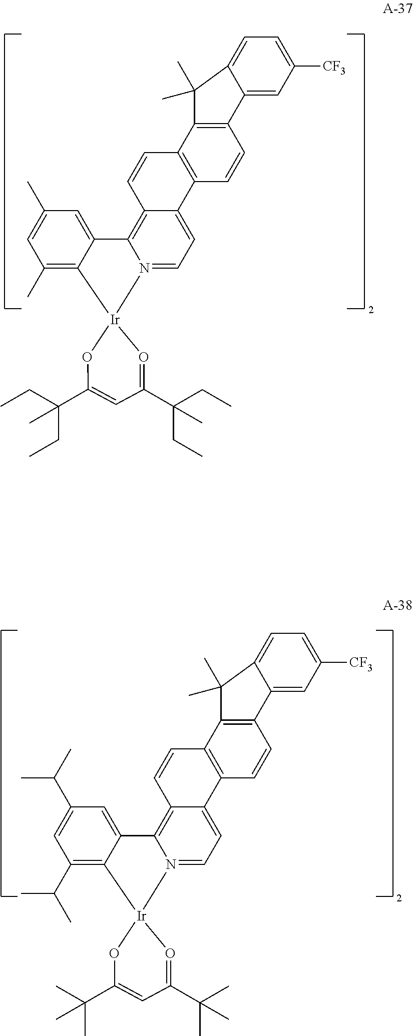

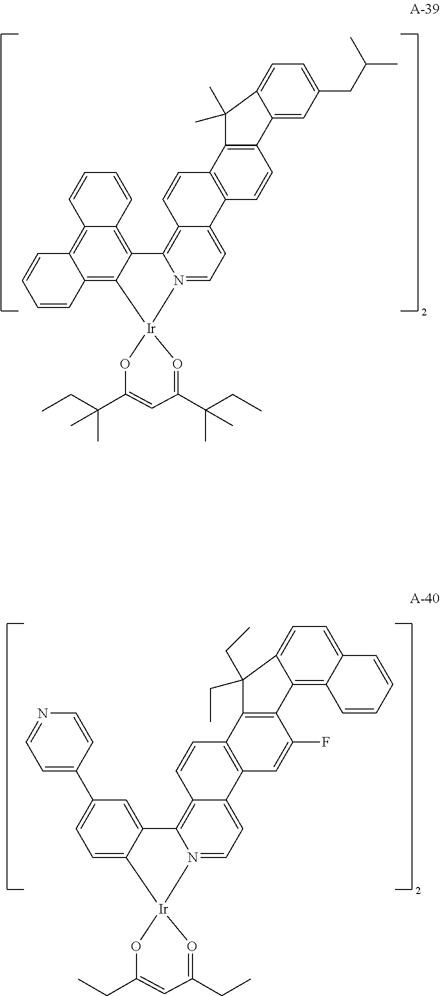

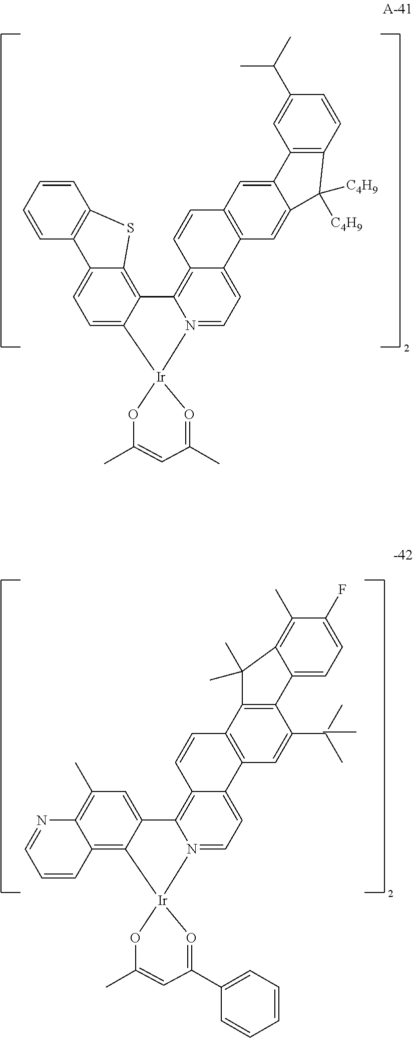

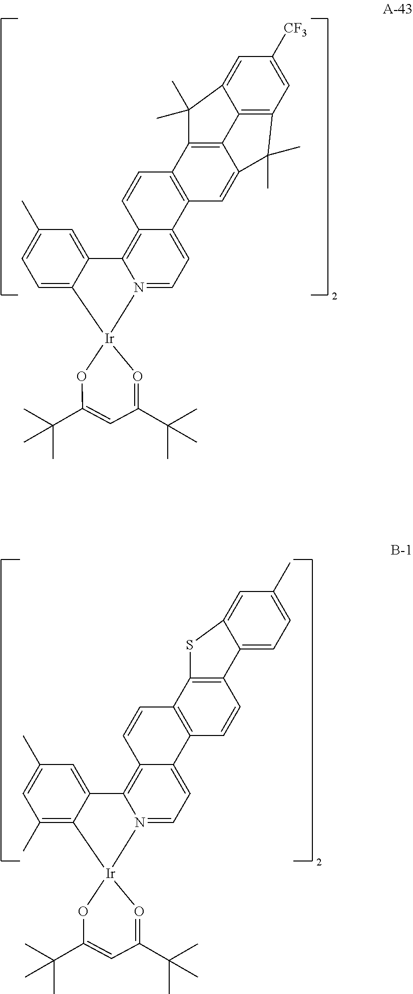

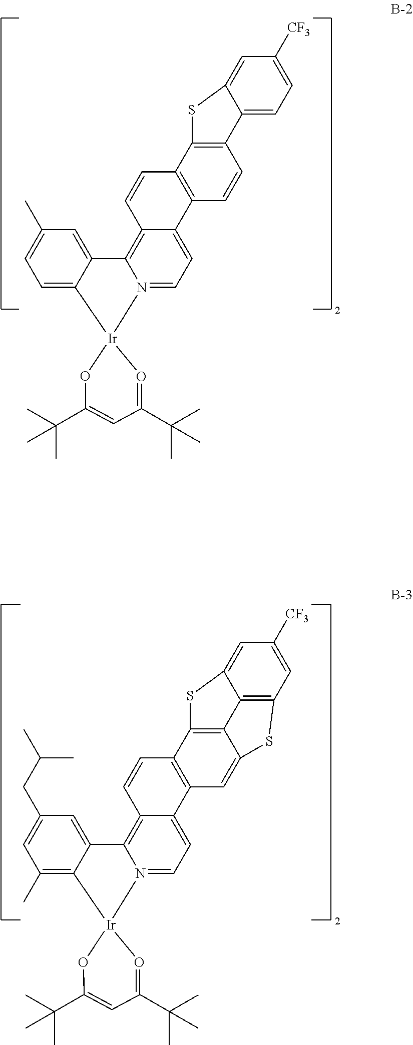

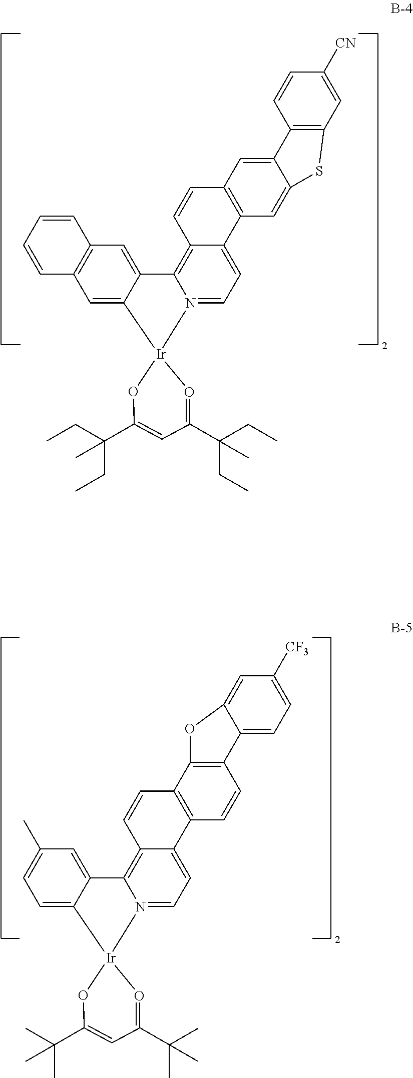

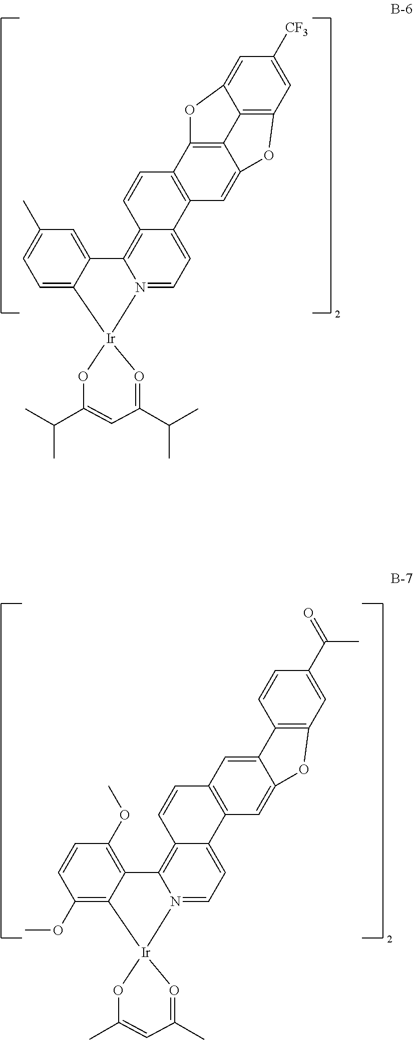

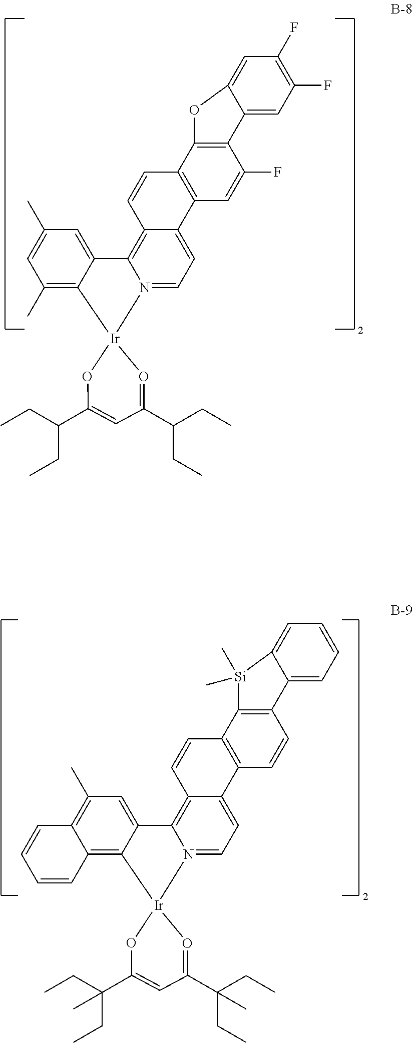

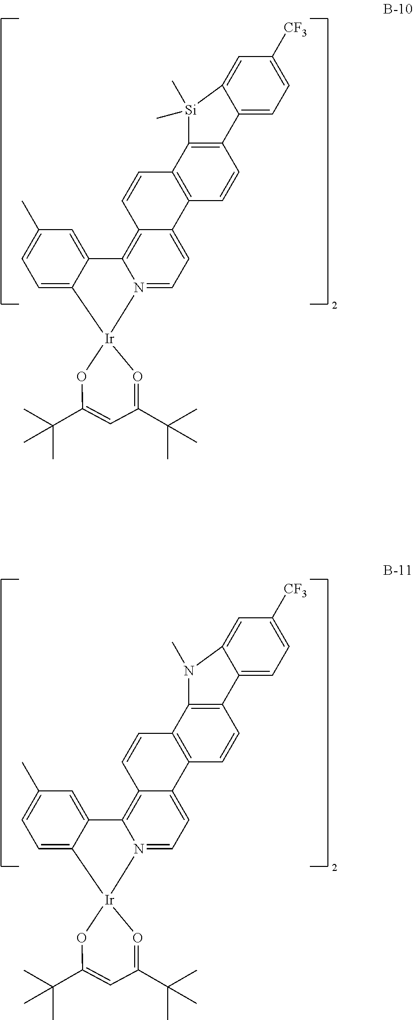

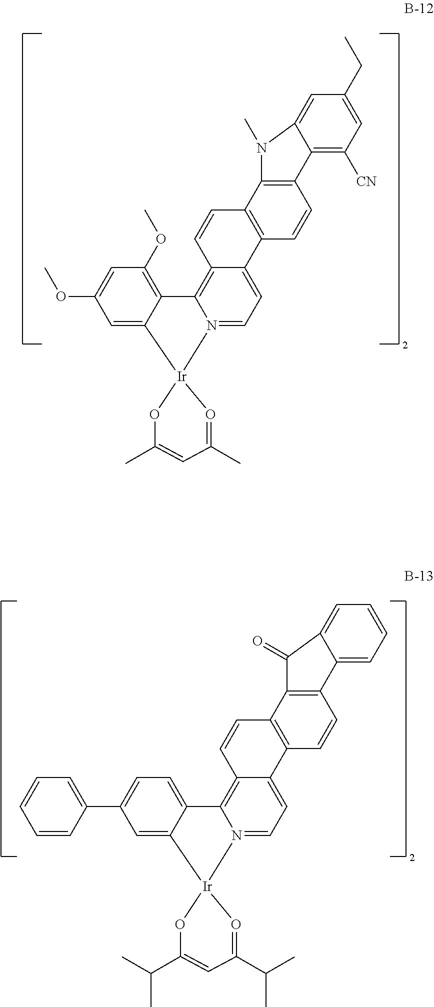

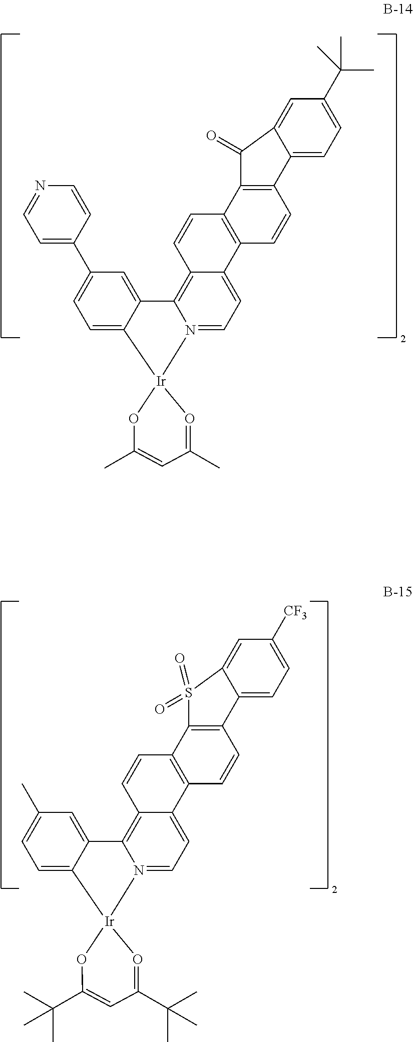

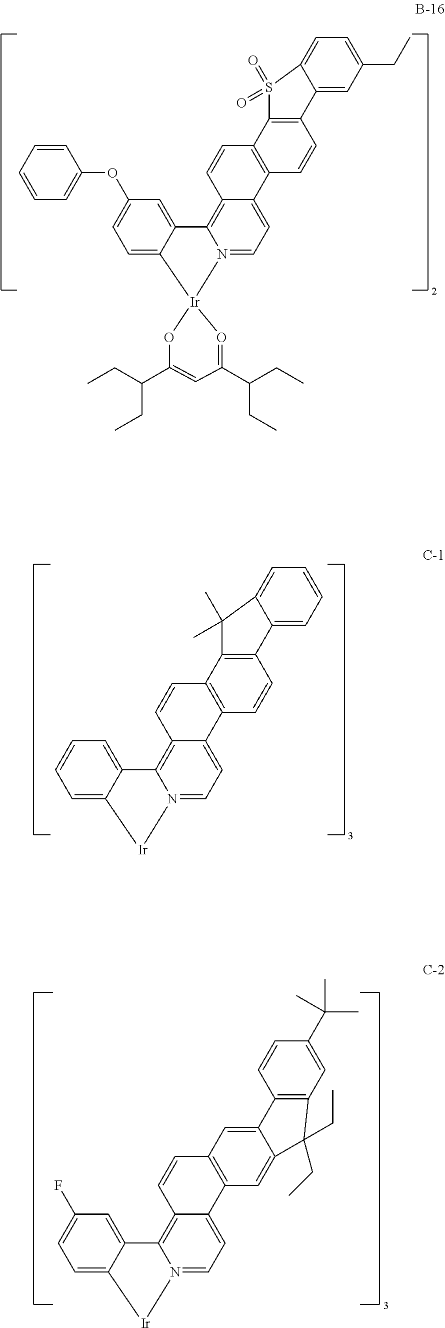

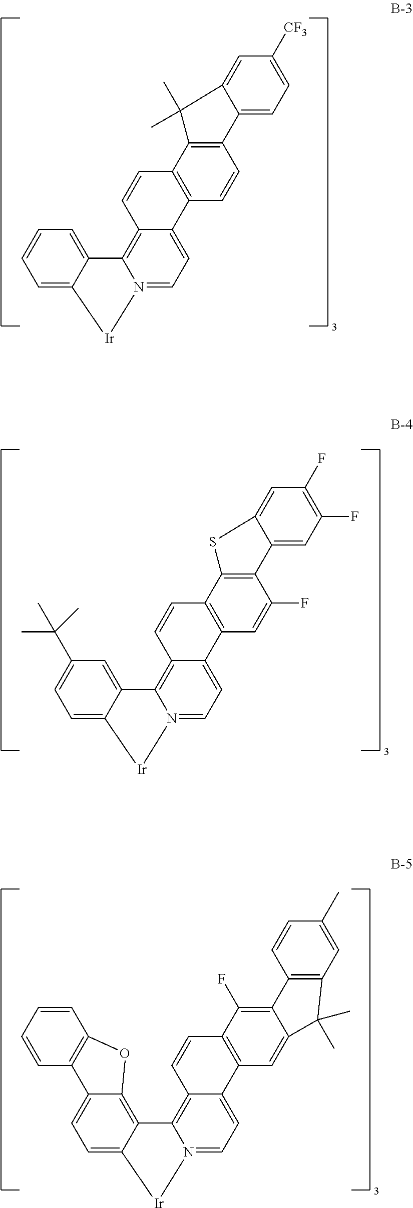

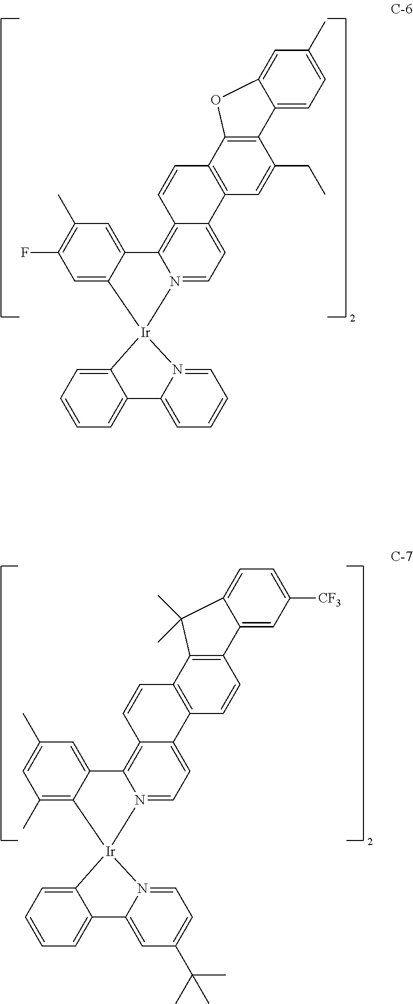

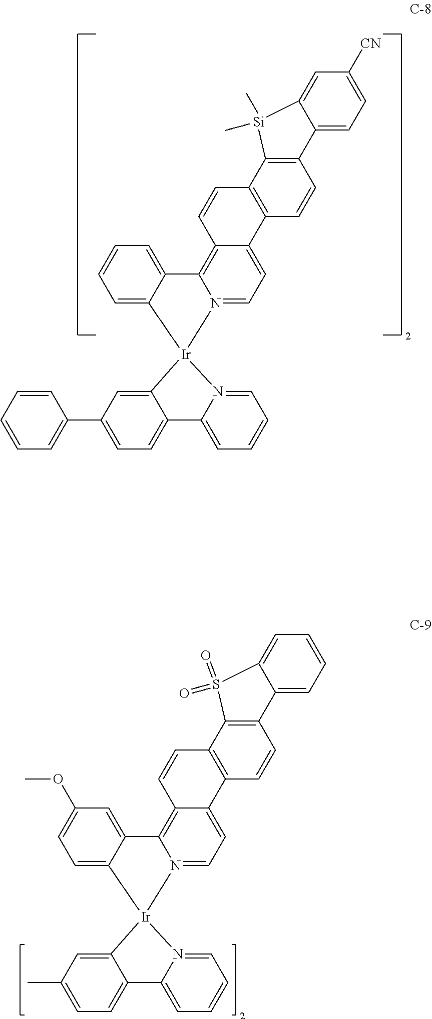

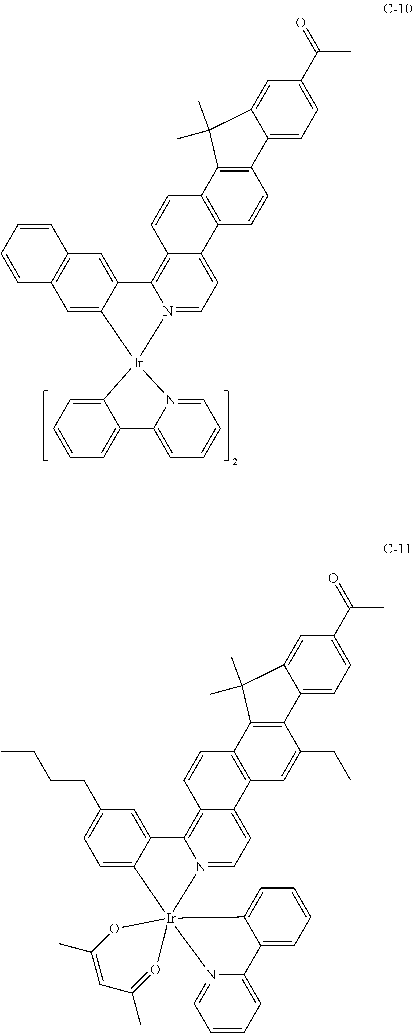

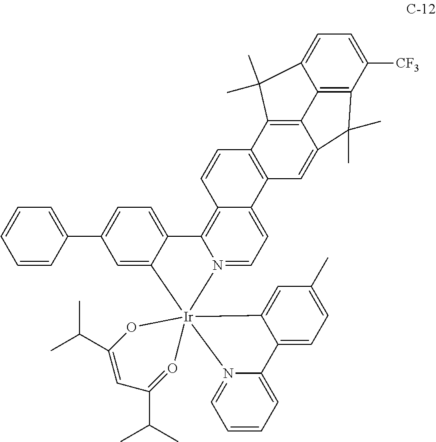

The example compounds described above are examples of the organic metal complex represented by general formula (1). Among the compounds described as examples, those in the A group are examples of an organic metal complex that includes two main ligands that have a five-membered ring structure that bonds the BIQ ring and another aromatic ring via a carbon atom, and one ancillary ligand represented by general formula (3). The five-membered ring structure that bonds the BIQ ring and another aromatic group includes only carbon atoms, and thus has a relatively low polarity and excellent compatibility with other organic molecules; thus, a light emission layer having a homogeneous composition can be formed. Furthermore, in some cases, the heat resistance, sublimability, and orientation property of the organic metal complex can be improved by selecting an appropriate ancillary ligand.

The B group concerns examples of an organic metal complex that has a five-membered ring structure bonding the BIQ ring and another aromatic ring with S, O, Si, N, C═O, or SO₂. These are effective when used in combination with another polar organic molecule since they have a polarity compared to carbon atoms and easily form hydrogen bonds.

The C group concerns an organic metal complex having three main ligands having a BIQ skeleton, and an organic metal complex having two main ligands having a BIQ skeleton and one ancillary ligand or one main ligand having a BIQ skeleton and two ancillary ligands. The organic metal complex having three main ligands having a BIQ skeleton are a stable organic metal complex due to its high molecular symmetry. The group of compounds having two main ligands having a BIQ skeleton and one ancillary ligand has an effect of lowering the vapor deposition temperature due to its low molecular weight. Particularly, an organic metal complex that contains 2-phenylpyridine as an ancillary ligand can be used as a compound that strikes a balance between molecular stability and vapor deposition temperature when appropriately combined with an appropriate BIQ skeleton-containing main ligand and the ancillary ligand.

In all of the organic metal complexes described above, the BIQ skeleton-including main ligand contributes to light emission, and the ligand forming a highly robust five-membered ring structure reduces the intramolecular structural changes and improves durability of the molecule. Moreover, the good direction and length of transition dipole moment increase the oscillator strength, resulting in high light emitting efficiency.

Next, an organic light emitting element of according to an embodiment is described. An organic light emitting element according to an embodiment includes at least a first electrode, a second electrode, and an organic compound layer disposed between these electrodes. One of the first electrode and the second electrode is an anode and the other is a cathode. In the organic light emitting element of this embodiment, the organic compound layer may be a single layer or a layered structure including multiple layers as long as a light emission layer is included. Here, when the organic compound layer is a layered structure including multiple layers, the organic compound layer may have, in addition to the light emission layer, a hole injection layer, a hole transport layer, an electron blocking layer, a hole/exciton blocking layer, an electron transport layer, an electron injection layer, etc. The light emission layer may be a single layer or a layered structure including multiple layers.

In the organic light emitting element of this embodiment, at least one layer in the organic compound layer contains the organic metal complex of the present embodiment. Specifically, the organic compound according to the present embodiment is contained in any one of the light emission layer, the hole injection layer, the hole transport layer, the electron blocking layer, the hole/exciton blocking layer, the electron transport layer, the electron injection layer, etc., described above. The organic metal complex of the present embodiment can be contained in the light emission layer.

In the organic light emitting element of the present embodiment, when the organic metal complex of the present embodiment is contained in the light emission layer, the light emission layer may be a layer solely composed of the organic metal complex of the present embodiment, or may be a layer composed of the organic metal complex of the present embodiment and other compounds. Here, when the light emission layer is a layer that contains the organic metal complex of the present embodiment and other compounds, the organic metal complex of the present embodiment may be used as a host or guest of the light emission layer. Alternatively, the organic metal complex may be used as an assist material that can be contained in the light emission layer. Here, the host refers to a compound that accounts for the largest mass ratio among the compounds constituting the light emission layer. The guest refers to a compound that accounts for a mass ratio smaller than that of the host among the compounds constituting the light emission layer, and that is responsible for main light emission. The assist material is a compound that accounts for a mass ratio smaller than that of the host among the compounds constituting the light emission layer, and that assists the light emission of the guest. Here, the assist material is also known as a second host. The host material may be referred to as a first organic compound, and the assist material may be referred to as a second organic compound. The first organic compound has a lowest excited singlet energy and a lowest excited triplet energy higher than those of the organic metal complex. The second organic compound may have a lowest excited triplet energy higher than that of the organic metal complex but lower than that of the first organic compound.

When the organic metal complex of the present embodiment is used as the guest of the light emission layer, the organic metal complex content in the light emission layer is preferably 0.01 mass % or more and 20 mass % or less and more preferably 0.1 mass % or more and 10 mass % or less.

The present inventors have conducted various studies and have found that when the organic metal complex of the present embodiment is used as a host or guest of the light emission layer, in particular, a guest of the light emission layer, an element that outputs light having high luminance at high efficiency and has extremely high durability can be obtained. This light emission layer may be a single layer or a multilayer, and the emission color of the present embodiment may be mixed with other colors by containing light emitting materials that have other emission colors. The multilayer refers to a state in which a light emission layer and another light emission layer are stacked on top of each other. In such a case, the emission color of the organic light emitting element is not particularly limited. The color may be white or an intermediate color. When the color is white, other light emission layers emit light of colors other than the emission color of the light emission layer containing the organic metal complex. Furthermore, the film is formed by vapor deposition or coating. Details thereof are described in the examples below.

When the organic metal complex of the present embodiment is contained in the light emission layer, a layer composed of an organic compound may be disposed between the light emission layer and the second electrode and/or between the light emission layer and the first electrode. Both layers may have a lowest excited triplet energy higher than that of the light emission layer.

The organic metal complex of the present embodiment can be used as a material constituting an organic compound layer other than the light emission layer constituting the organic light emitting element of the present embodiment. Specifically, the organic metal complex may be used as a material constituting layers such as an electron transport layer, an electron injection layer, a hole transport layer, a hole injection layer, and a hole blocking layer. In such a case, the emission color of the organic light emitting element is not particularly limited and may be white or an intermediate color.

Here, in addition to the organic metal complex of the present embodiment, low-molecular-weight and high-molecular-weight hole injection compounds or hole transport compounds, compounds that can function as a host, light-emitting compounds, electron injection compounds, electron transport compounds, etc., that are known in the art can be used if necessary.

In the description below, the examples of these compounds are described.

The hole injection/transport material can be a material having high hole mobility so that injection of holes from the anode is facilitated and the injected holes can be transported to the light emission layer. In order to reduce deterioration of the film quality, such as crystallization, in the organic light emitting element, a material having a high glass transition point can be used. Examples of the low-molecular-weight and high-molecular-weight materials that have a hole injection/transport property include triarylamine derivatives, arylcarbazole derivatives, phenylenediamine derivatives, stilbene derivatives, phthalocyanine derivatives, porphyrin derivatives, poly(vinylcarbazole), poly(thiophene), and other conductive polymers. Furthermore, the aforementioned hole injection/transport materials can be used in the electron blocking layer. Specific examples of the compound that is used as the hole injection/transport material are described below, and these examples are not limiting.

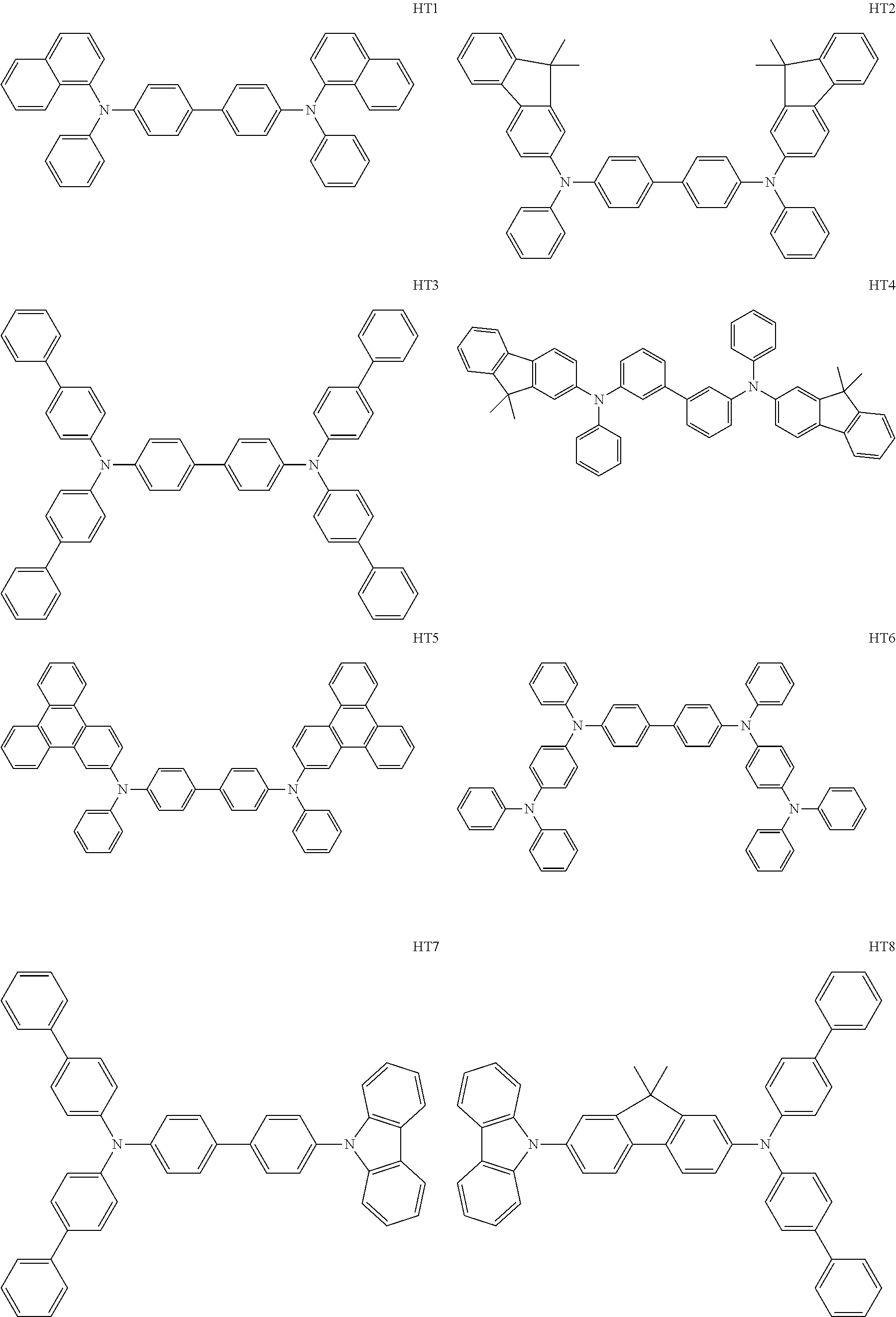

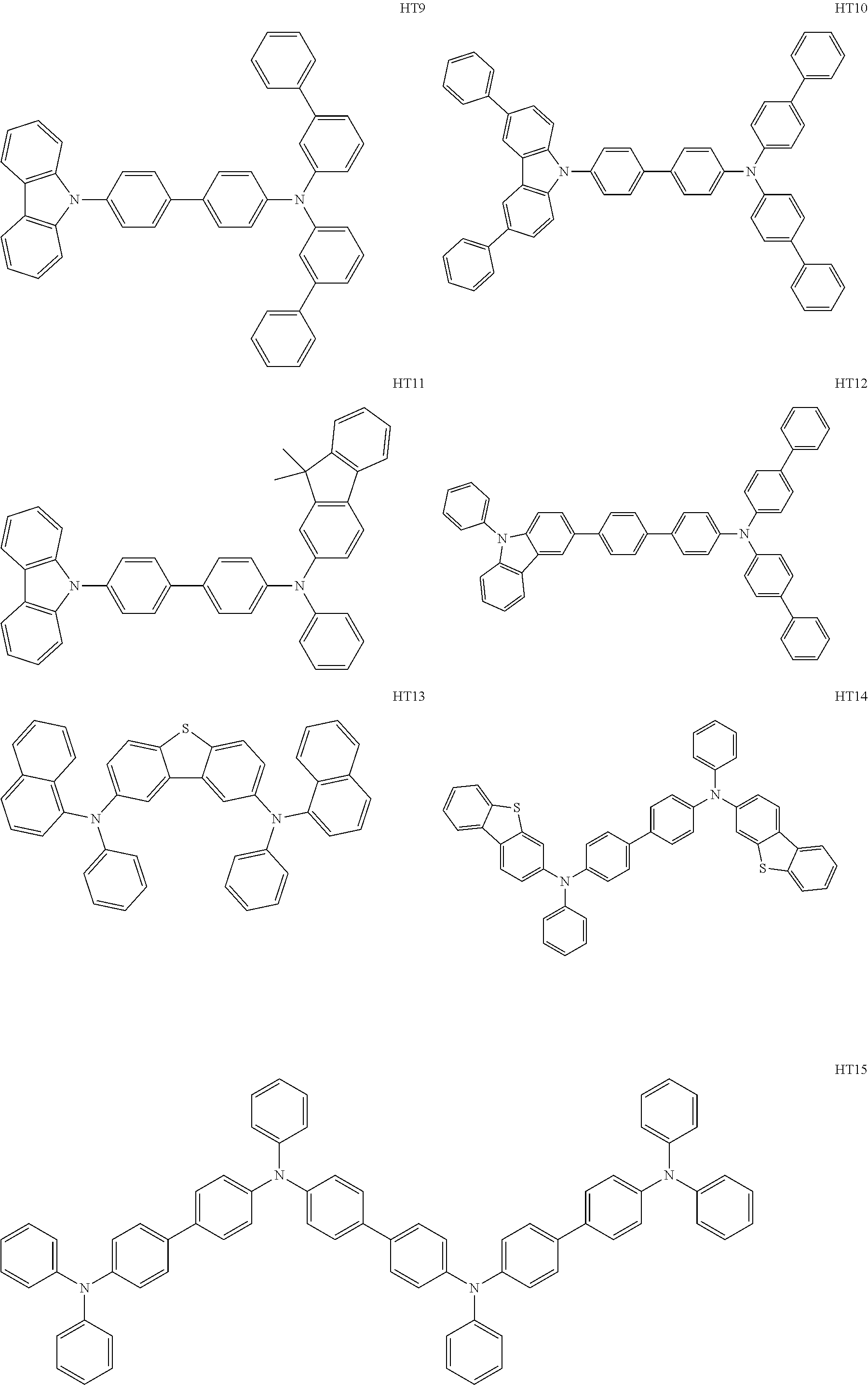

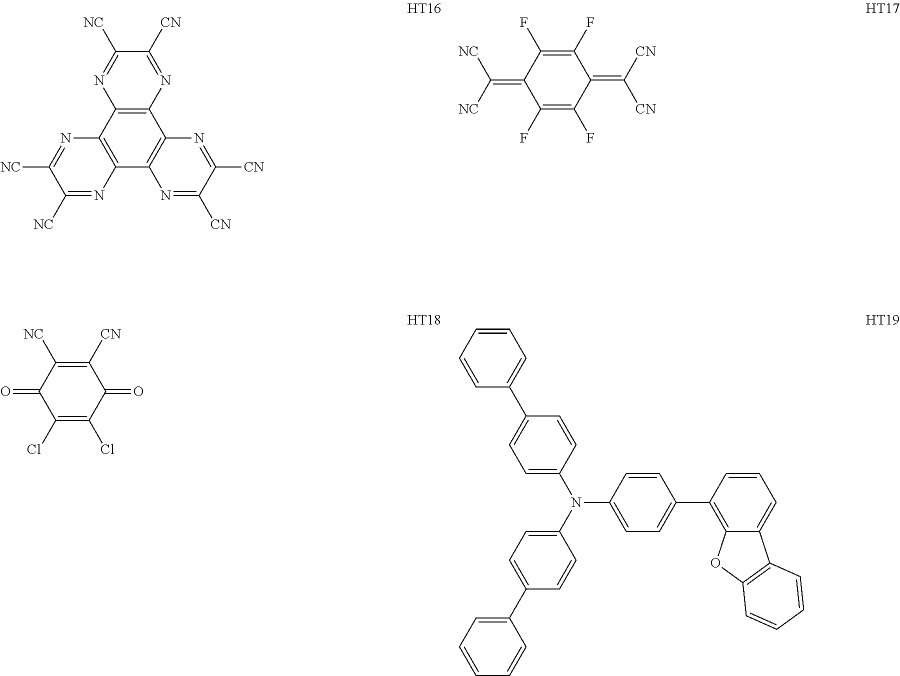 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Among the hole injection/transport materials described above. HT16 to HT18 can decrease the drive voltage when used in a layer in contact with the anode. HT16 is widely used in organic light emitting elements. HT2, HT3, HT4, HT5, HT6, HT10, and HT12 may be used in the organic compound layer adjacent to the organic compound layer containing HT16. Furthermore more than one materials may be used in one organic compound layer.

Examples of the light emitting material mainly related to the light emitting function include fused ring compounds (e.g., fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes such as tris(8-quinolinolate)aluminum, iridium complexes, platinum complexes, rhenium complexes, copper complexes, europium complexes, ruthenium complexes, and polymer derivatives such as poly(phenylenevinylene) derivatives, poly(fluorene) derivatives, and poly(phenylene) derivatives.

Specific examples of the compound that is used as the light emitting material are described below, and these examples are not limiting.

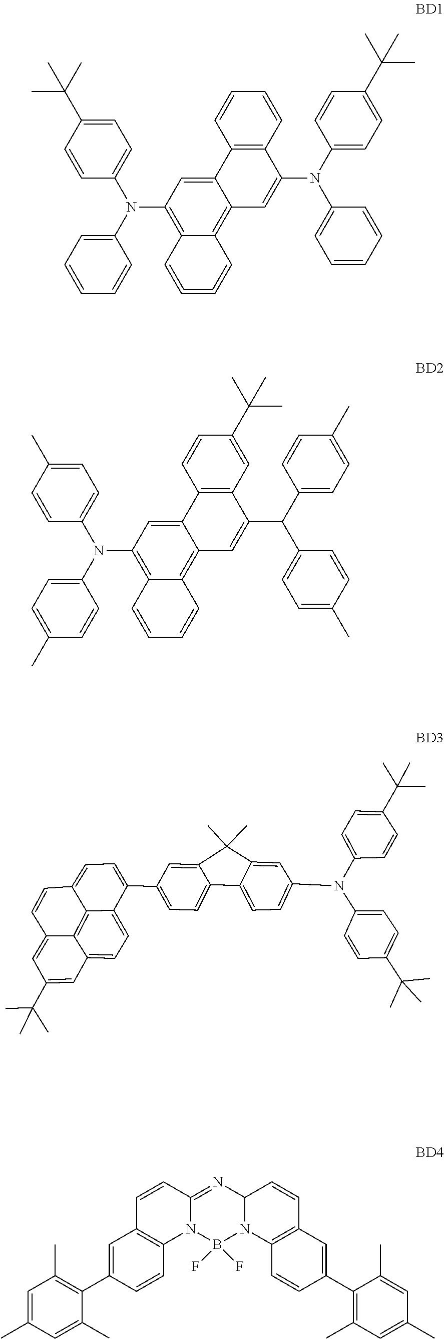

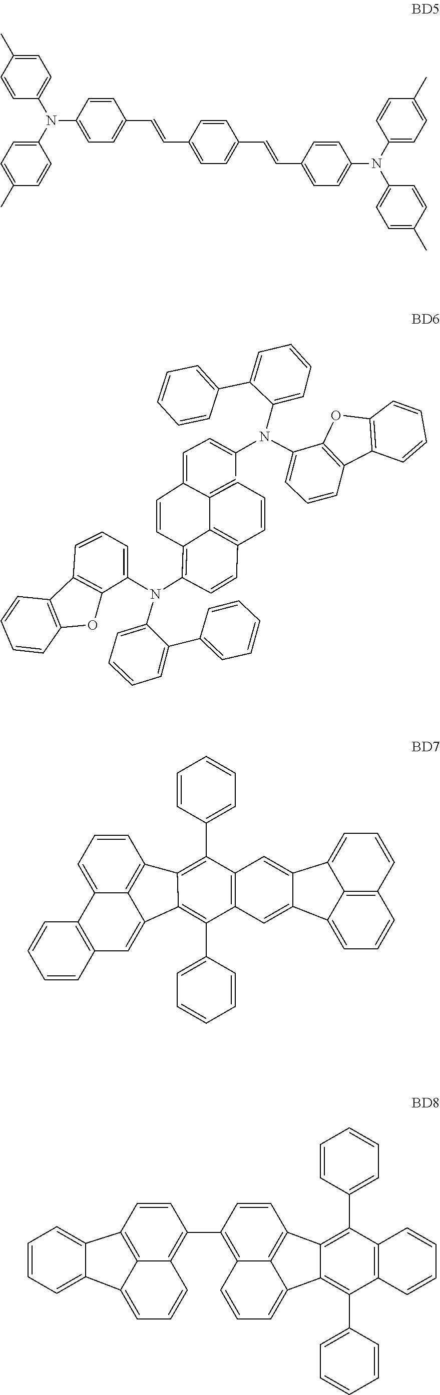

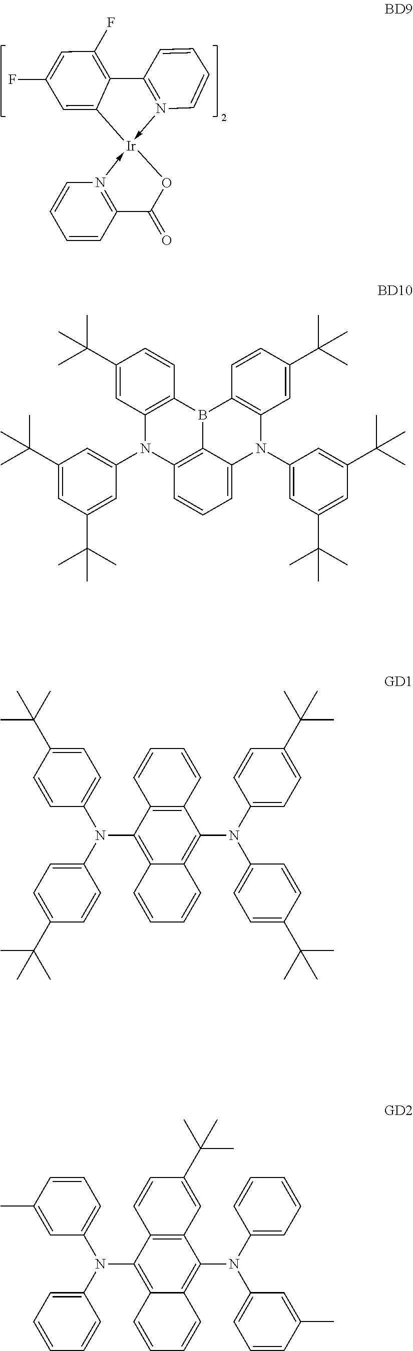

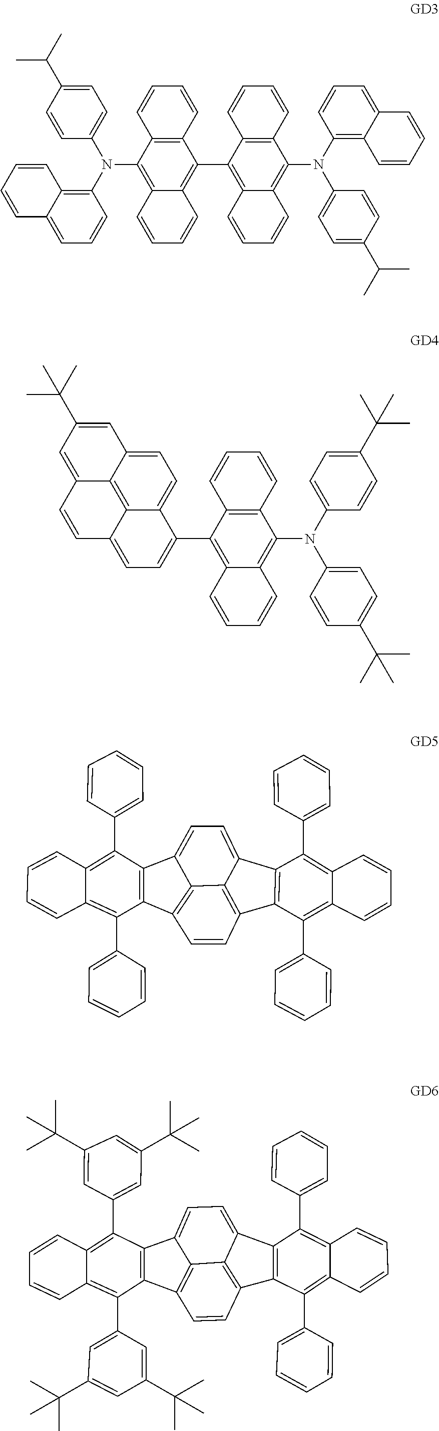

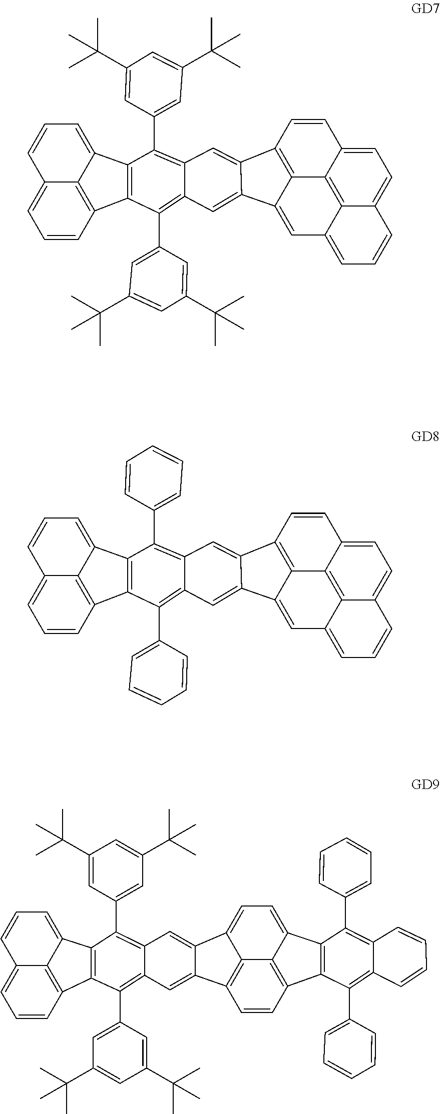

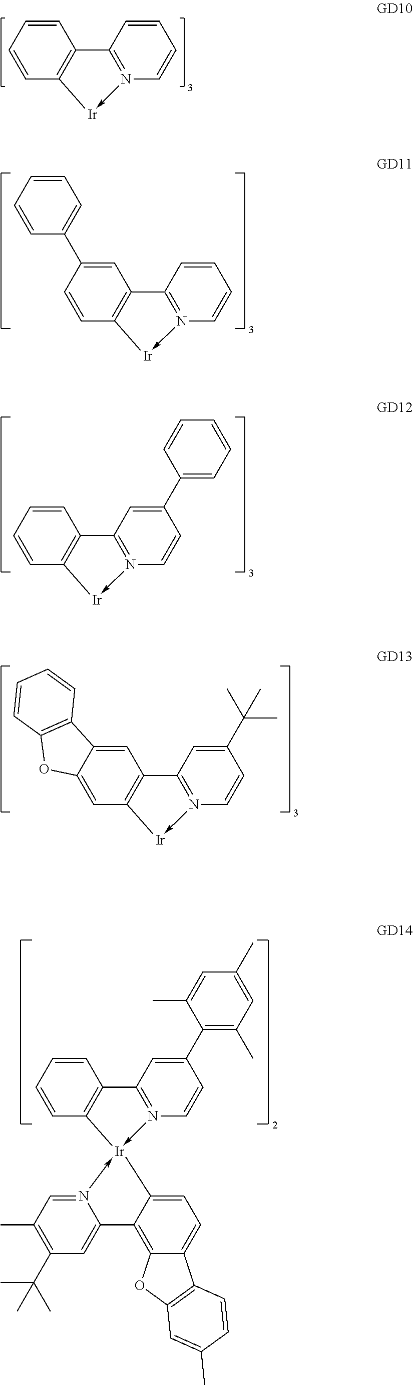

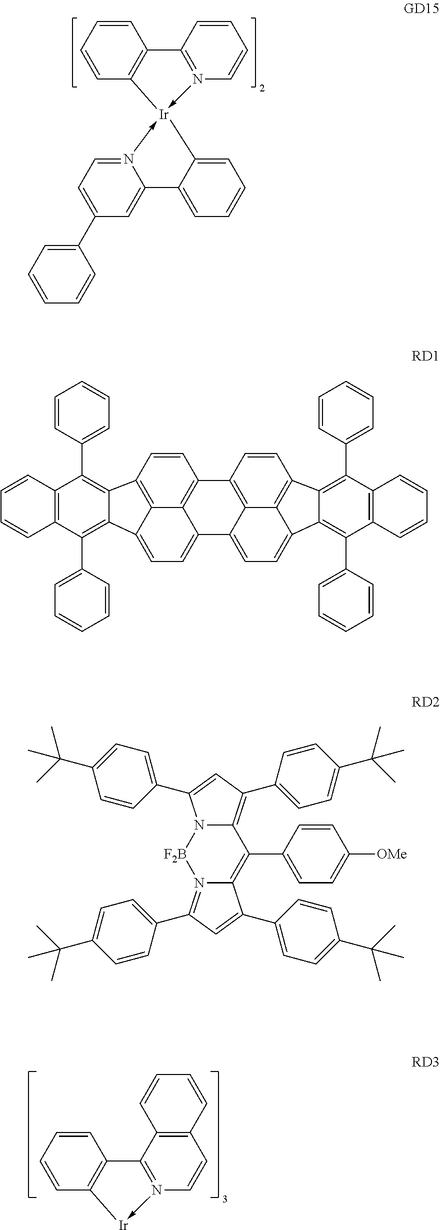

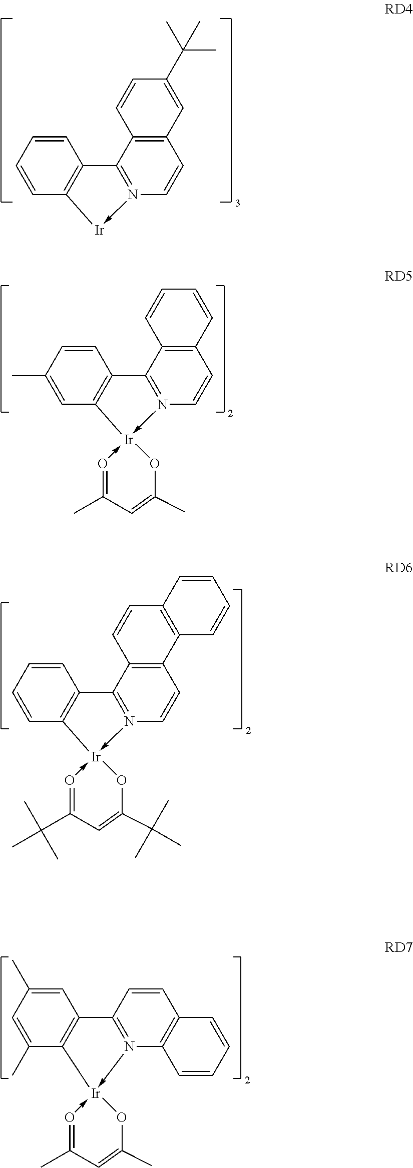

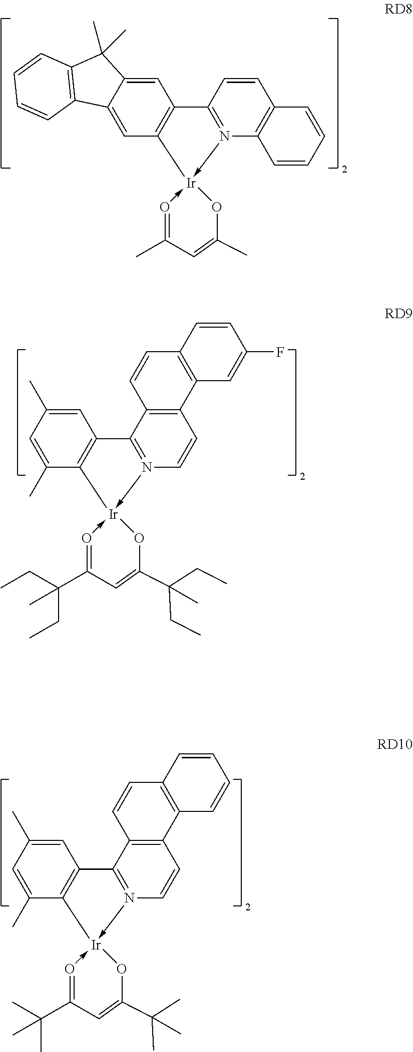

When the light emitting material is a hydrocarbon compound, the decrease in light emitting efficiency due to exciplex formation and the color purity degradation caused by changes in emission spectrum of the light emitting material due to exciplex formation can be reduced.

A hydrocarbon compound is a compound constituted by carbon and hydrogen only, and, among the example compounds described above, BD7, BD8, GD5 to GD9, and RD1 are the hydrocarbon compounds.

When the light emitting material is a fused polycycle containing a five-membered ring, oxidation rarely occurs due to its high ionization potential and the element exhibits high durability and long lifetime. Among the example compounds described above, BD7, BD8, GD5 to GD9, and RD1 are the five member ring-containing fused polycycle.

Examples of the light emission layer host or the light emission assist material contained in the light emission layer include aromatic hydrocarbon compounds and derivatives thereof, carbazole derivatives, dibenzofuran derivatives, dibenzothiophene derivatives, organoaluminum complexes such as tris(8-quinolinolato)aluminum, and organoberyllium complexes.

Specific examples of the compound that is used as the light emission layer host or light emission assist material contained in the light emission layer are described below, and these examples are not limiting.

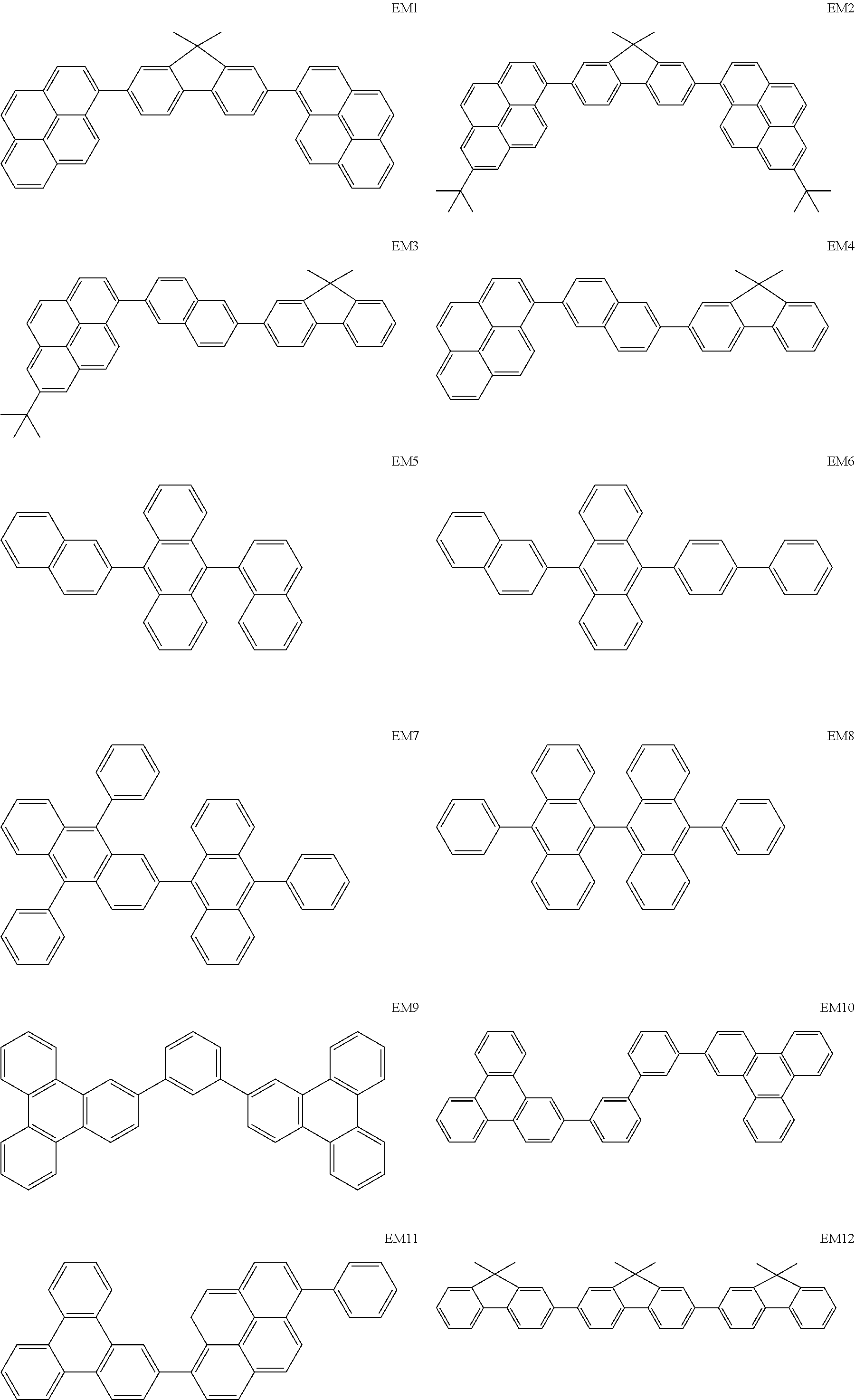

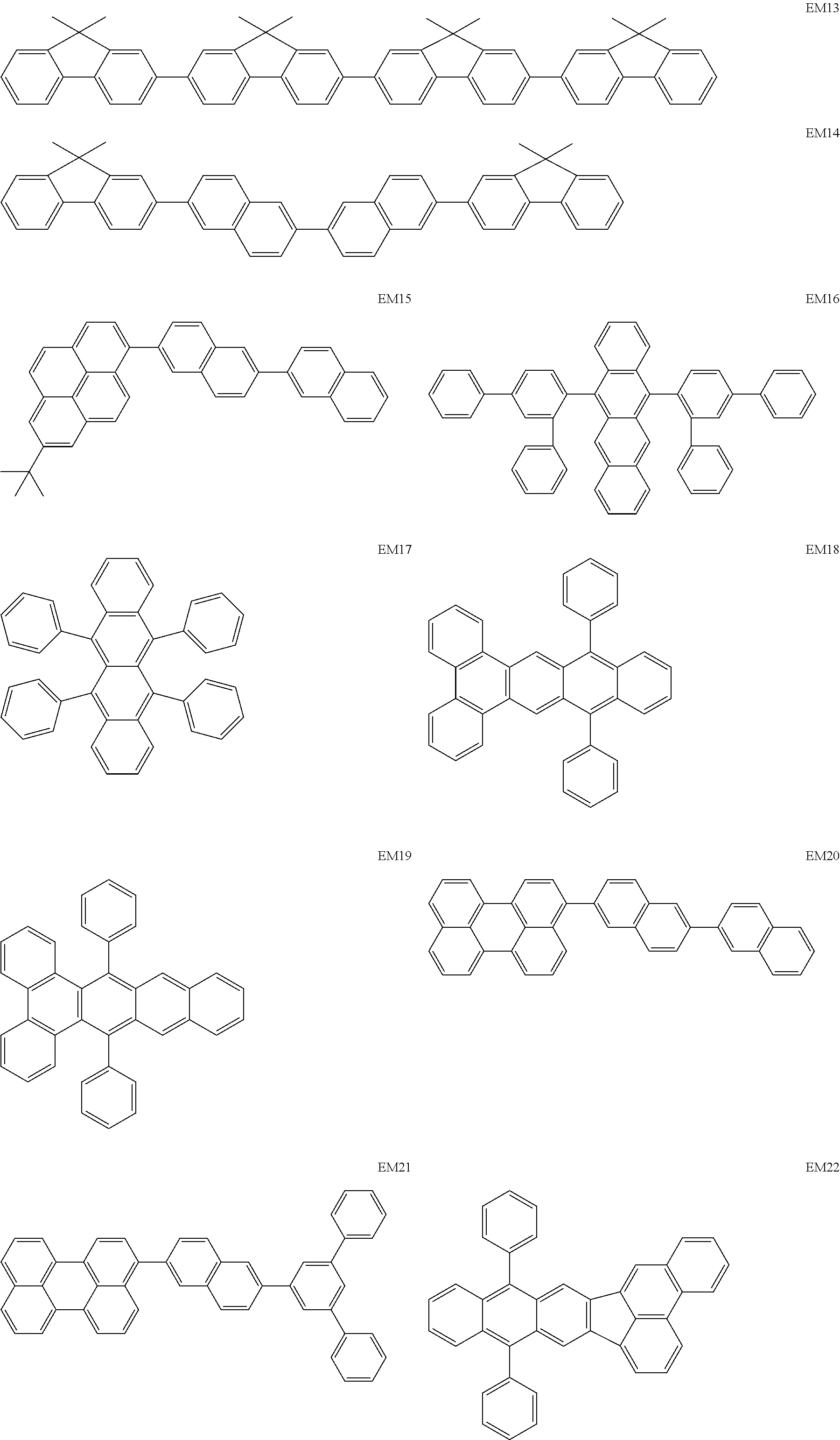

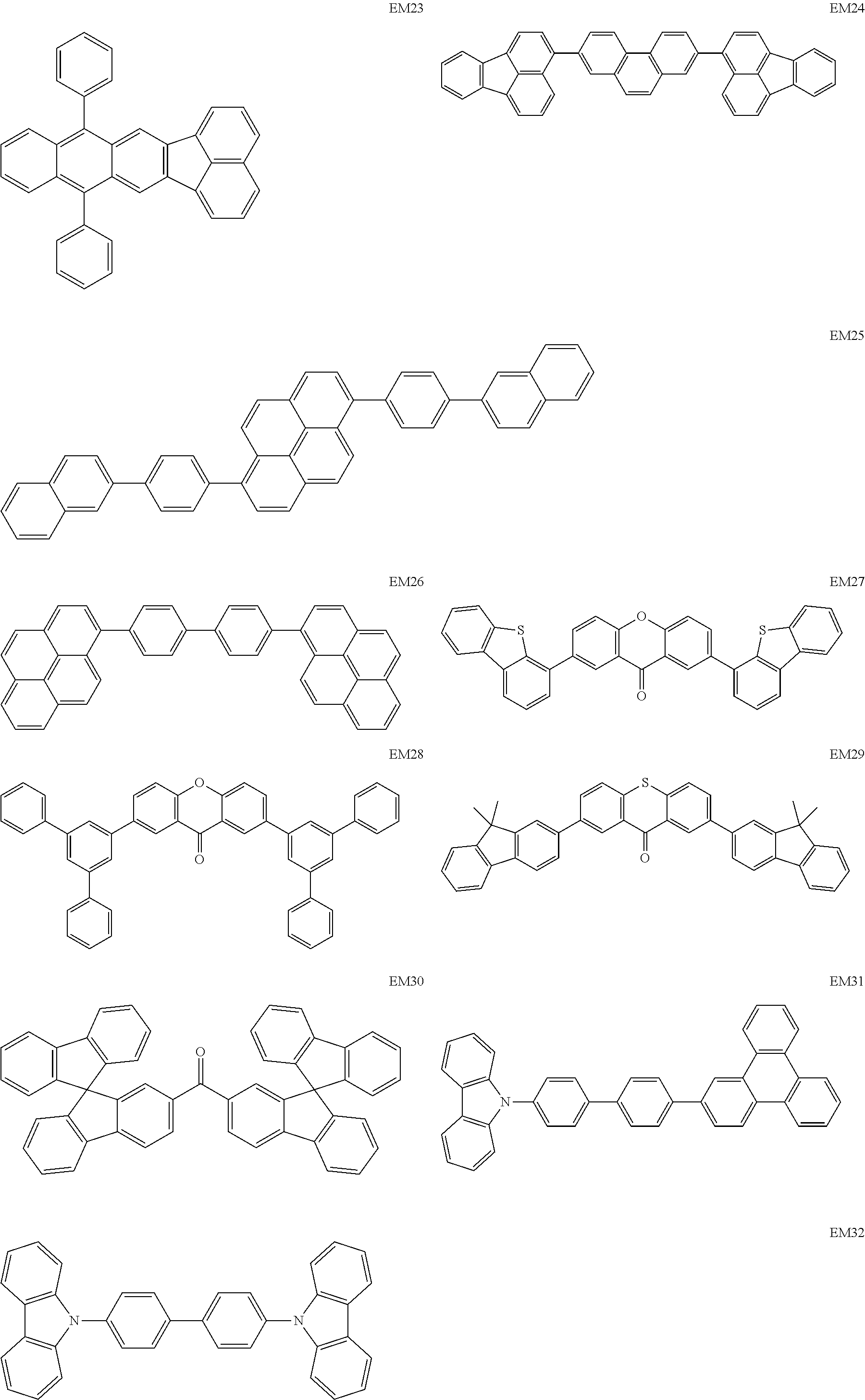

When the host material is a hydrocarbon compound, the organic metal complex of the present embodiment easily traps electrons and holes and thus the effect of increasing the efficiency is prominent. Among the example compounds described above, EM1 to EM26 are examples of this.

The electron transport material can be freely selected from those which can transport electrons injected from the cathode to the light emission layer, and the selection is made in consideration of the balance with the hole mobility of the hole transport material. Examples of the material having an electron transport property include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused ring compounds (e.g. fluorene derivatives, naphthalene derivatives, chrysene derivatives, and anthracene derivatives). Furthermore, the aforementioned electron transport materials can also be used in the hole blocking layer.

Specific examples of the compound that is used as the electron transport material are described below, and these examples are not limiting.

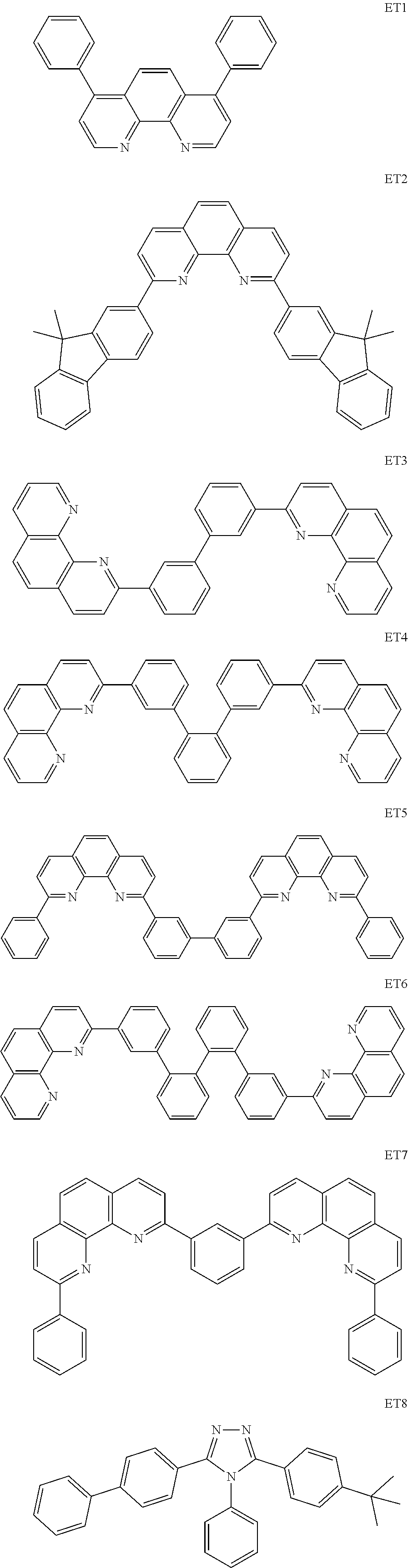

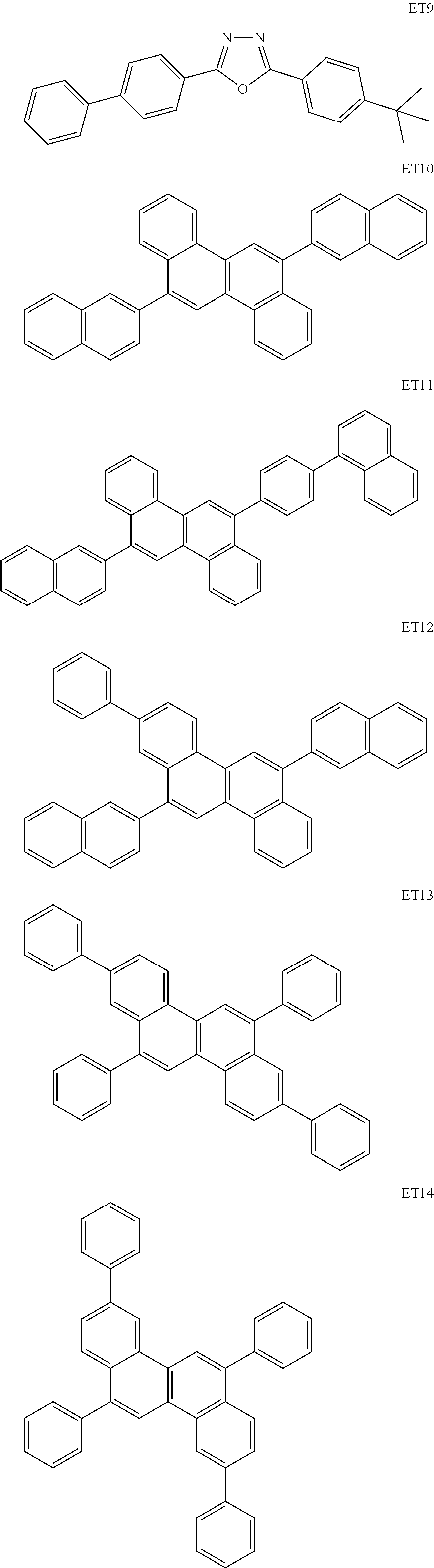

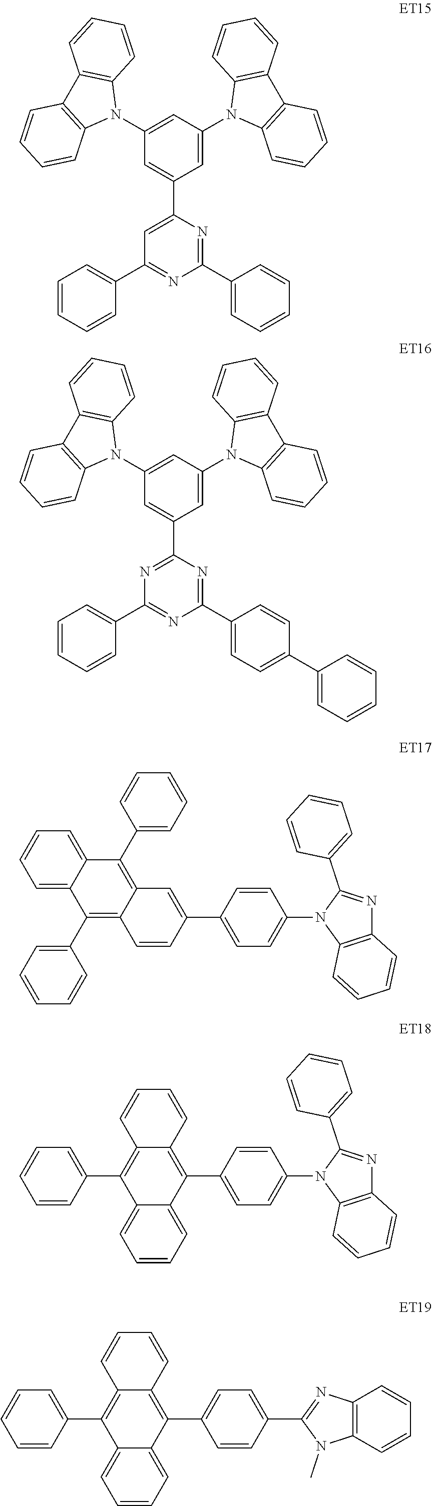

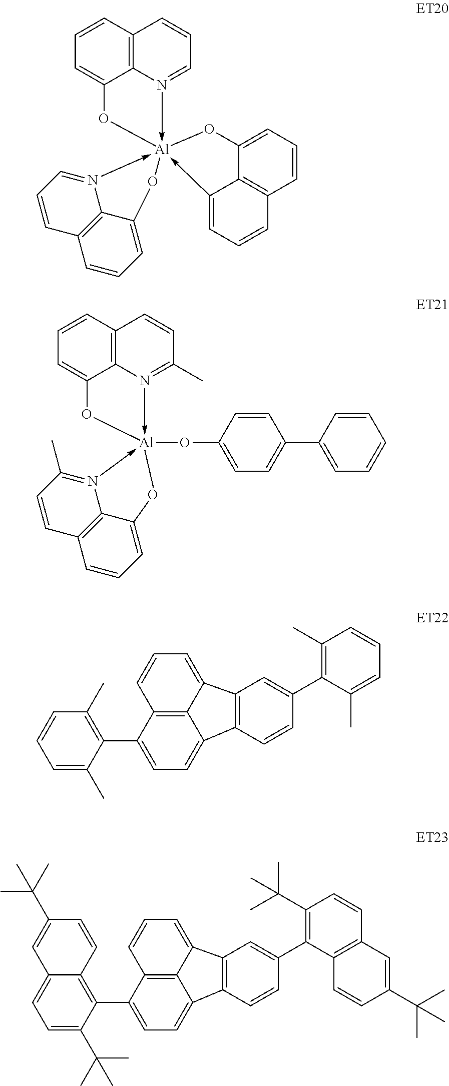

The electron injection material can be freely selected from those which can facilitate electron injection from the cathode, and the selection is made in consideration of the balance with the hole injectability. As the organic compound, n-type dopants and reducing dopants are also contained. Examples thereof include compounds containing alkali metals such as lithium fluoride, lithium complexes such as lithium quinolinol, benzimidazolidene derivatives, imidazolidene derivatives, fulvalene derivatives, and acridine derivatives.

These can be used in combination with the electron transport materials described above.

Organic compound layers other than the light emission layer (the hole injection layer, the hole transport layer, the electron blocking layer, the hole blocking layer, the electron transport layer, the electron injection layer, etc.) can be formed by employing a dry process such as a vacuum evaporation method, an ionization evaporation method, sputtering, or plasma. Instead of the dry process, a wet process of forming layers by a known coating method (for example, spin coating, dipping, casting, a LB method, or an ink jet method) that involves using an appropriate solvent for dissolving can be employed.

Here, when layers are formed by a vacuum evaporation method, a solution coating method, or the like, crystallization rarely occurs, and the stability overtime is excellent. When films are formed by a coating method, an appropriate binder resin may be used in combination.

Examples of the binder resin include, but are not limited to, polyvinyl carbazole resin, polycarbonate resin, polyester resin, ABS resin, acrylic resin, polyimide resin, phenolic resin, epoxy resin, silicone resin, and urea resin.

These binder resins may be used alone or in combination as a mixture as a homopolymer or a copolymer. If necessary, additives such as known plasticizers, oxidation inhibitors, and ultraviolet absorbents may be used in combination.

### Ink Composition

Next, a luminescent ink composition according to an embodiment is described.

An ink composition of according to an embodiment contains at least one organic metal complex represented by general formula (1) above, and a solvent. The organic metal complex represented by general formula (1) has good solubility in organic solvents, and thus can be used as an ink composition. Moreover, by using the ink composition of the present embodiment, layers composed of organic compounds constituting the organic light emitting element of the present embodiment, in particular, a light emission layer, can be produced by a coating method, and thus large-area elements can be easily formed at a relatively low cost. Examples of the solvent that dissolves the compound represented by general formula (1) include toluene, xylene, mesitylene, dioxane, methylnaphthalene, tetrahydrofuran, diglyme, 1,2-dichlorobenzene, and 1,2-dichloropropane. These organic solvents can be used alone or in combination of two or more. Among these, organic solvents that have an appropriate evaporation rate, specifically, a boiling point of about 70° C. to 200° C., can be used since thin films having even thickness can be easily obtained. The ink composition of the present embodiment may further contain compounds that serve as additives. Examples of the compounds that serve as additives include the aforementioned known light emission layer host or light emission assist materials, hole transport materials, light emitting materials, and electron transport materials.

The concentration of the organic metal complex represented by general formula (1) in the ink composition is preferably 0.05 mass % or more and 20 mass % or less and more preferably 0.1 mass % or more and 5 mass % or less.

The ink composition can be formed into films by a spin coating method, a bar coating method, a slit coating method, an ink jet method, a nozzle coating method, a casting method, a gravure printing method, or the like.

The organic light emitting element of the present embodiment can be configurated into a display device such as a display by forming the organic light emitting element of the present embodiment on electrodes formed in a pixel pattern.

### Structure of Organic Light Emitting Element

The organic light emitting element is obtained by forming an insulating layer, a first electrode, an organic compound layer, and a second electrode on a substrate. A protection layer, a color filter, a micro lens, etc., may be formed on the second electrode. When a color filter is to be formed, a planarization layer may be formed between the color filter and the protection layer. The planarization layer can be formed by using an acrylic resin or the like. The same applies to the case in which a planarization layer is formed between a color filter and a micro lens.

The individual members of the organic light emitting element other than the organic compound layers will now be described.

### Substrate

Examples of the substrate include quartz, glass, a silicon wafer, a resin, and a metal. Switching elements such as transistors and conductor lines may be disposed on the substrate, and an insulating layer may be disposed thereon. The material for the insulating layer may be any as long as contact holes can be formed therein to form a conductor line to the first electrode and as long as the insulation from the conductor line to be disconnected can be secured. For example, resins such as polyimide, silicon oxide, or silicon nitride can be used.

### Electrodes

One of the first electrode and the second electrode is an anode and the other is a cathode. When an electric field is to be applied in a direction in which the organic light emitting element emits light, an electrode with a higher potential is an anode, and the other electrode is a cathode. In other words, an electrode that supplies holes to the light emission layer is an anode, and an electrode that supplies electrodes is a cathode.

The material constituting the anode can have a work function as high as possible. For example, single metals such as gold, platinum, silver, copper, nickel, palladium, cobalt, selenium, vanadium, and tungsten, mixtures and alloys containing these, and metal oxides such as tin oxide, zinc oxide, indium oxide, indium tin oxide (ITO), and indium zinc oxide can be used. Furthermore, a conductive polymer such as polyaniline, polypyrrole, or polythiophene can be used.

These electrode materials may be used alone, or in combination of two or more. The anode may be a single layer or may include multiple layers.

When the electrode is used as a reflection electrode, chromium, aluminum, silver titanium, tungsten, or molybdenum or an alloy thereof can be used, or multiple layers of these metals can be stacked and used. The aforementioned materials can function as a reflection film that does not serve as an electrode. When the electrode is used as a transparent electrode, an oxide transparent conductive layer such as indium tin oxide (ITO) or indium zinc oxide can be used, but these examples are not limiting. Photolithography can be employed in forming the electrodes.

In contrast, the material constituting the cathode can have a work function as low as possible. Examples thereof include alkali metals such as lithium, alkaline earth metals such as calcium, single metals such as aluminum, titanium, manganese, silver, lead, and chromium, and mixtures thereof. Alternatively, an alloy containing these single metals can also be used. For example, magnesium-silver, aluminum-lithium, aluminum-magnesium, silver-copper, zinc-silver, etc., can be used. A metal oxide such as indium tin oxide (ITO) can also be used. These electrode materials may be used alone, or in combination of two or more. The cathode may be a single layer or may include multiple layers. In particular, silver can be used, and, in order to reduce aggregation of silver, a silver alloy can be used. As long as the aggregation of silver can be reduced, the alloying ratio may be any. For example, the silver-to-other metal ratio may be 1:1, 3:1, or the like.

An oxide conductive layer such as ITO may be used as a cathode to form a top-emission element, or a reflection electrode such as aluminum (Al) may be used to form a bottom-emission element without any limitation. The method for forming the cathode is not particularly limited, but a DC or AC sputtering method provides good film coverage and easily decreases resistance.

### Protection Layer

A protection layer may be formed on the second electrode. For example, an absorbent-laden glass is bonded onto the second electrode to reduce penetration of water and the like into the organic compound layer and to decrease occurrence of the display failure. In another embodiment, a passivation film such as silicon nitride may be formed on the second electrode to reduce penetration of water and the like into the organic compound layers. For example, the second electrode formed may be conveyed into another chamber without breaking the vacuum, and a 2 μm-thick silicon nitride film may be formed by a CVD method to obtain a protection layer. A protection layer may be formed by an atomic layer deposition method (ALD method) after film formation by the CVD method. The material for the films formed by the ALD method may be any, and may be silicon nitride, silicon oxide, aluminum oxide, or the like. Silicon nitride may be formed by a CVD method on a film formed by an ALD method. The film formed by the ALD method may have a thickness smaller than that of the film formed by the CVD method. Specifically, the thickness may be 50% or less or 10% or less.

### Color Filter

A color filter may be formed on the protection layer. For example, a color filter may be formed on a different substrate by considering the size of the organic light emitting element, and this substrate may be bonded with the substrate on which the organic light emitting element has been formed, or a color filter may be formed on the aforementioned protection layer by photolithography through patterning. The color filter may be composed of a polymer.

### Planarization Layer

A planarization layer may be disposed between the color filter and the protection layer. The planarization layer is disposed for the purpose of reducing irregularities of the underlying layer. Such a layer is also referred to as a material resin layer without limiting its purpose. The planarization layer may be composed of an organic compound and may have a low molecular weight or a high molecular weight, particularly, a high molecular weight.

Planarization layers may be formed above and under the color filter, and may be composed of the same or different materials. Specific examples thereof include polyvinyl carbazole resin, polycarbonate resin, polyester resin, ABS resin, acrylic resin, polyimide resin, phenolic resin, epoxy resin, silicone resin, and urea resin.

### Micro Lens

An organic light emitting device that includes an organic light emitting element may include an optical member, such as a micro lens, on the light emitting side. The micro lens can be composed of an acrylic resin, an epoxy resin, or the like. The micro lens may be used for the purposes of increasing the amount of light and the direction of light emitted from the organic light emitting device. The micro lens may have a hemispherical shape. With the micro lens has a hemispherical shape, there is a tangent parallel to the insulating layer among the tangents contacting the hemisphere, and the tangent point between this tangent and the hemisphere is the apex of the micro lens. The apex of the micro lens can also be determined in the same manner by using any cross sectional view. In other words, in a cross sectional view, there is a tangent parallel to the insulating layer among the tangents contacting the semicircle of the micro lens, and the tangent point between this tangent and the semicircle is the apex of the micro lens.

The mid point of the micro lens can also be defined. In a section of the micro lens, an imaginary line segment extending from a point where an arc shape ends to a point where another arc shape ends is drawn, and the mid point of that line segment can be referred to as the mid point of the micro lens. The section used to identify the apex and the mid point may be a section taken perpendicular to the insulating layer.

### Counter Substrate

A counter substrate may be disposed on the planarization layer. The counter substrate takes its name from its position that opposes the aforementioned substrate. The material constituting the counter substrate may be the same as the aforementioned substrate. The counter substrate may be a second substrate if the aforementioned substrate is a first substrate.

### Structure of Device Equipped With Organic Light Emitting Element

### Pixel Circuit

A light emitting device equipped with the organic light emitting element of the present embodiment may have a pixel circuit connected to the organic light emitting element. The pixel circuit may be of an active matrix type that independently controls light emission of a first organic light emitting element and a second organic light emitting element. The active matrix circuit may be voltage-programmed or current-programmed. The drive circuit has a pixel circuit for each pixel. The pixel circuit may include an organic light emitting element, a transistor that controls the emission luminance of the organic light emitting element, a transistor that controls the light emission timing, a capacitor that retains the gate voltage of the transistor that controls the emission luminance, and a transistor for establishing the connection to GND without a light emitting element.

The light emitting device has a display region and a peripheral region disposed around the display region. The display region has pixel circuits, and the peripheral region has display control circuit. The mobility of the transistor constituting the pixel circuit may be smaller than the mobility of the transistor that constitutes the display control circuit.

The gradient of the current-voltage characteristics of the transistor constituting the pixel circuit may be smaller than the gradient of the current-voltage characteristics of the transistor constituting the display control circuit. The gradient of the current-voltage characteristics can be measured by what is commonly known as Vg-Ig characteristics.

The transistors constituting the pixel circuit are transistors that are connected to the organic light emitting elements, such as a first organic light emitting element.

### Pixels

A light emitting device equipped with the organic light emitting element of the present embodiment has multiple pixels. Each pixel has subpixels that emit colors different from one another. The subpixels may emit light of RGB colors, for example.

The pixel has a region also known as a pixel aperture that emits light. This region is the same as the first region.

The pixel aperture may be 15 μm or less or 5 μm or more. Specifically, the pixel aperture may be, for example, 11 μm, 9.5 μm, 7.4 μm, or 6.4 μm. The subpixel intervals may be 10 μm or less, specifically, 8 μm, 7.4 μm, or 6.4 μm.

Pixels may be arranged in a known matrix in a plan view. Examples thereof include a stripe matrix, a delta matrix, a pentile matrix, and a Bayer matrix. The shape of the subpixels in a plan view may be any known shape. Examples thereof include rectangular shapes such as an oblong shape or a rhombus shape, and hexagonal shapes. Naturally, the shape does not have to be exact, and any shape close to an oblong shape is considered an oblong shape. The shape of the subpixels and the pixel arrangement may be used in combination.

### Usage of Organic Light Emitting Element

An organic light emitting element according to one embodiment can be used as a member that constitutes a display device or a lighting apparatus. Other examples of the usage include an exposure light source of an electrophotographic image forming device, a backlight of a liquid crystal display device, and a light emitting device that has a color filter on a white light source.

The display device may be an information processing device that includes an image input unit through which image information is input from an area CCD, a linear CCD, a memory card, or the like, an information processing unit that processes the input information, and a display unit that displays the input image.

Furthermore, a display unit of an imaging device or an ink jet printer may have a touch panel function. The driving system of the touch panel function may be the infrared radiation, electrostatic capacitance, resistance film, electrostatic capacitance, or any other system. The display device may be used in a display unit of a multifunctional printer.

Next, a display device according to an embodiment is described with reference to the drawings.

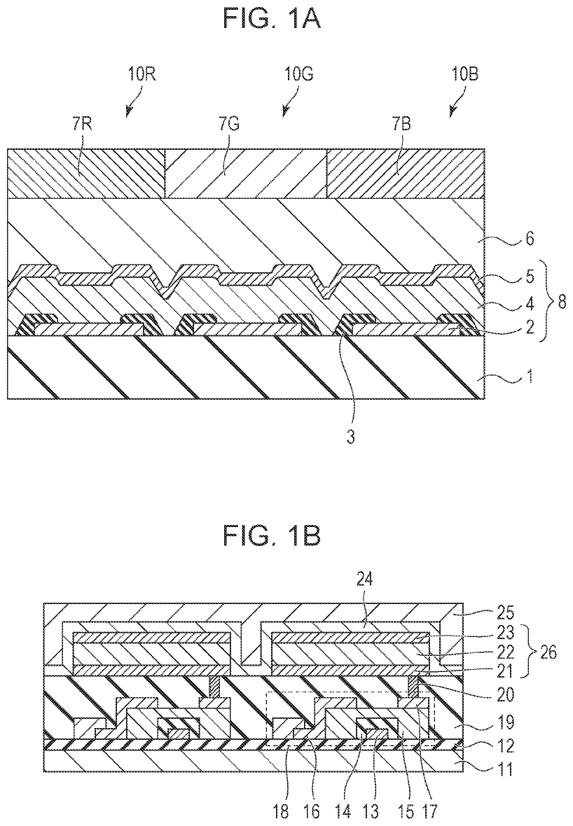

FIG. 1A and 1B are schematic cross sectional views illustrating examples of a display device that includes an organic light emitting element of the present embodiment and transistors connected to the organic light emitting element.

FIG. 1A illustrates one example of a pixel which is a constitutional feature of the display device according to the present embodiment. The pixel has subpixels 10. The subpixels are classified as 10R, 10G, and 10B according to their emission color. The emission color may be distinguished on the basis of the wavelength of the light emitted from the light emission layer, or a color filter or the like may be used to selectively transmit or change the color of the light emitted from the subpixels. Each of the subpixels has a first electrode 2 that serves as a reflection electrode disposed on an interlayer insulating layer 1, an insulating layer 3 that covers edges of the first electrode 2, an organic compound layer 4 that covers the first electrode 2 and the insulating layer 3, a second electrode 5, a protection layer 6, and a color filter 7. The first electrode 2, the organic compound layer 4, and the second electrode 5 constitute an organic light emitting element 8.

The interlayer insulating layer 1 may have a transistor and a capacitor element below or inside thereof.

The transistor and the first electrode 2 may be electrically connected to each other via a contact hole or the like not illustrated in the drawing.

The insulating layer 3 is also referred to as a bank or a pixel isolation film. The insulating layer 3 covers the edges of the first electrode 2 and surrounds the first electrode 2. The part where the insulating layer 3 is absent is in contact with the organic compound layer 4 and functions as a light-emitting region.

The second electrode 5 may be a transparent electrode, a reflection electrode, or a semi-transmissive electrode.

The protection layer 6 reduces penetration of moisture into the organic compound layer 4. Although the protection layer 6 is depicted as one layer in the drawing, the protection layer 6 may include multiple layers. An inorganic compound layer and an organic compound layer may be provided for each layer.

The color filters 7 are classified as 7R, 7G, and 7B according to their colors. The color filters may be formed on the planarizing film not illustrated in the drawing. A resin protection layer not illustrated in the drawing may be disposed on the color filters. The color filters may be formed on the protection layer 6. Alternatively, the color filters may be formed on a counter substrate such as a glass substrate and then bonded with the substrate.

A display device illustrated in FIG. 1B includes an organic light emitting element 26 and a TFT 18 as one example of the transistor. Specifically, there are a substrate 11, such as glass or silicon, and an insulating layer 12 on top of the substrate 11, and a TFT 18 that includes a gate electrode 13, a gate insulating film 14, a semiconductor layer 15, a drain electrode 16, and a source electrode 17 is disposed on the insulating layer 12. An insulating film 19 is disposed on top of the TFT 18, and a contact hole 20 formed in the insulating film 19 connects an anode 21 of the organic light emitting element 26 to the source electrode 17.

The type of electrical connection for the electrodes (anode 21 and cathode 23) included in the organic light emitting element 26 and the electrodes (source electrode 17 and drain electrode 16) included in the TFT 18 is not limited to the one illustrated in FIG. 1B. In other words, the type of electrical connection may be any as long as one of the anode 21 and the cathode 23 is electrically connected to one of the source electrode 17 and the drain electrode 16. TFT stands for thin film transistor.

A first protection layer 24 and a second protection layer 25 are disposed on the cathode 23 to reduce deterioration of the organic light emitting element.

The emission luminance of the organic light emitting element 26 of the present embodiment is controlled by the TFT 18, and, by providing multiple organic light emitting elements 26 in-plane, an image can be displayed by using emission luminance.

The display device illustrated in FIG. 1B uses a transistor as a switching element, but may use a different switching element instead.

The transistor used in the display device illustrated in FIG. 1B is not limited to a TFT having an active layer on an insulating surface of a substrate and may be a transistor that uses a single-crystal silicon wafer. The active layer may be a non-single-crystal silicon such as amorphous silicon or microcrystalline silicon, or a non-single-crystal oxide semiconductor such as indium zinc oxide or indium gallium zinc oxide.

Alternatively, a transistor made of a low-temperature polysilicon or an active matrix driver formed on a substrate such as a Si substrate may be used. The phrase “on the substrate” can also mean “inside the substrate”. Whether a transistor is formed in the substrate or a TFT is used is selected according to the size of the display unit; for example, when the size is about 0.5 inches, organic light emitting elements may be formed on a Si substrate. Here, the phrase “formed in the substrate” means that the transistor is produced by processing a substrate, such as a Si substrate, itself. In other words, “transistor in the substrate” can also be considered as that the substrate and the transistor are integrated.

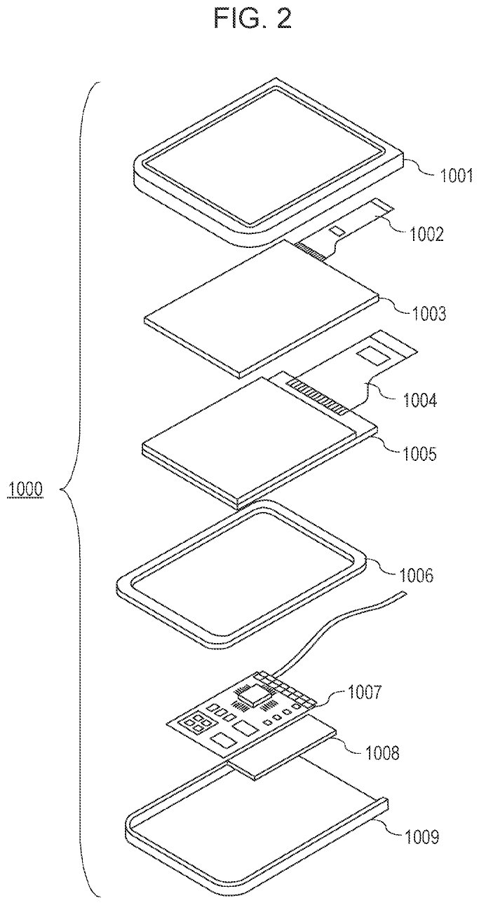

FIG. 2 is a schematic diagram illustrating one example of a display device according to an embodiment. A display device 1000 includes an upper cover 1001 and a lower cover 1009, and a touch panel 1003, a display panel 1005, a frame 1006, a circuit substrate 1007, and a battery 1008 that are interposed between these covers. The touch panel 1003 and the display panel 1005 are respectively connected to flexible print circuits FPC 1002 and 1004. Transistors are printed on the circuit substrate 1007. When the display device is not a portable appliance, the battery 1008 may be omitted, and even when the display device is a portable appliance, the battery 1008 may be provided at a different position.

The display device of the present embodiment may include red, green and blue color filters. The color filters may be arranged so that red, green and blue are arranged in a delta matrix.

The display device of the present embodiment may be used in a display unit of a portable terminal. Such a display device may have both a display function and an operation function. Examples of the portable terminal include mobile phones such as smart phones, tablets, and head-mount displays.

The display device of the present embodiment may be used in a display unit of an imaging device that includes an optical unit having multiple lenses, and an imaging element that receives light that has passed through the optical unit. The imaging device may include a display unit that displays the information acquired by the imaging element. The display unit may be exposed to the outside of the imaging device or may be disposed in a finder. The imaging device may be a digital camera or a digital camcorder.

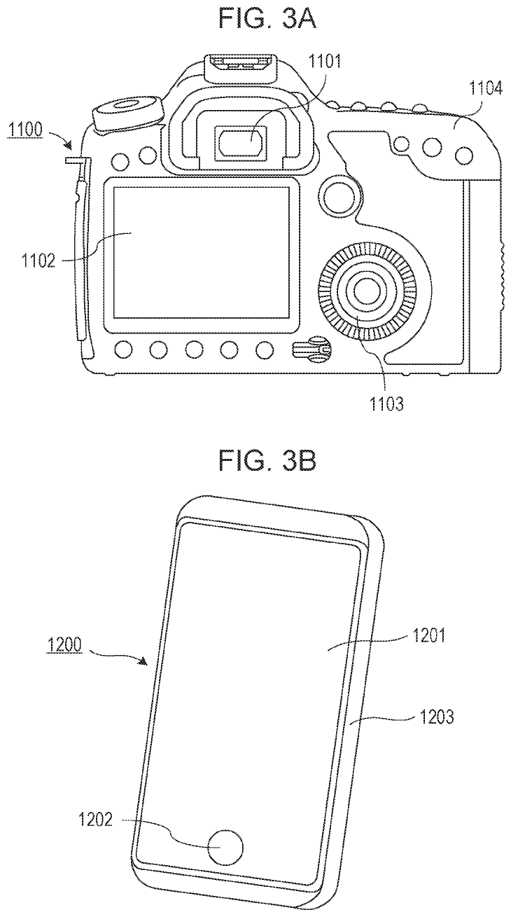

FIG. 3A is a schematic diagram illustrating one example of the imaging device according to an embodiment. An imaging device 1100 includes a view finder 1101, a rear display 1102, an operation unit 1103, and a casing 1104. The view finder 1101 may include the display device according to the present embodiment. In such a case, the display device may display not only the image to be captured but also the environment information, imaging instructions, etc. The environment information may include the intensity of external light, the direction of the external light, the speed in which a photographic subject moves, and a possibility of the photographic subject becoming shielded by a shielding material.

Since the timing for imaging is very short, the information may be displayed as quickly as possible. Accordingly, a display device that uses organic light emitting element of the present embodiment can be used. This is because the organic light emitting element has a high response speed. A display device that uses an organic light emitting element is more suitable for use in a device that requires a high display speed than liquid crystal display devices.

The imaging device 1100 has an optical unit not illustrated in the drawing. The optical unit has multiple lenses, and an image is focused on the imaging element contained in the casing 1104. The multiple lenses can adjust the focal point by adjusting the relative positions thereof. This operation can be automated. The imaging device may also be referred to as a photoelectric conversion device. The photoelectric conversion device can employ an imaging method that involves a method for detecting the difference from a previous image, a method for always cutting out an image from a recorded image, or the like instead of sequential imaging.

FIG. 3B is a schematic diagram illustrating one example of electronic equipment according to an embodiment. Electronic equipment 1200 includes a display unit 1201, an operation unit 1202, and a casing 1203. The casing 1203 may include a circuit, a print substrate having the circuit, a battery, and a communication unit. The operation unit 1202 may be a button or a touch panel-system sensitive unit. The operation unit may be a biometric unit that performs, for example, unlocking through fingerprint recognition. The electronic equipment that includes the communication unit can also be called communication equipment. The electronic equipment may further have a camera function when equipped with a lens and an imaging element. The image captured through the camera function is displayed on the display unit. Examples of the electronic equipment include smart phones and laptop computers.

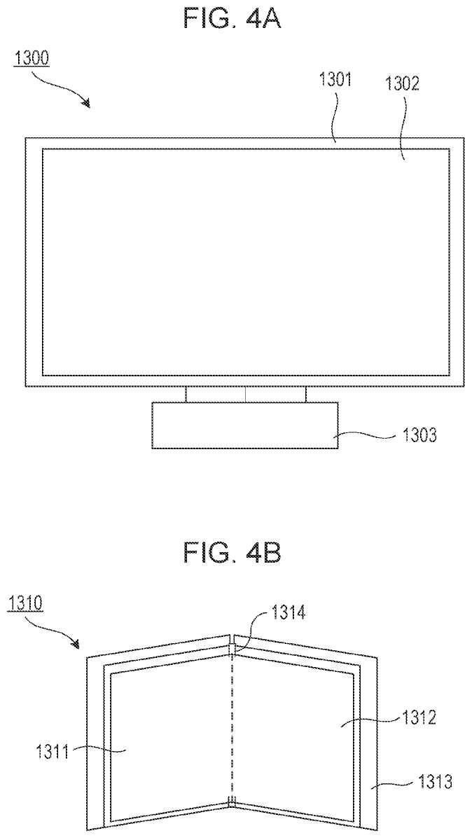

FIGS. 4A and 4B are schematic views illustrating some examples of a display apparatus of according to an embodiment. FIG. 4A illustrates a display apparatus such as a television monitor or a PC monitor. A display apparatus 1300 includes a frame 1301 and a display unit 1302. The light emitting device of the present embodiment may be used in the display unit 1302.

The display apparatus further includes a base 1303 that supports the frame 1301 and the display unit 1302. The base 1303 is not limited to the type illustrated in FIG. 4A. The lower edge of the frame 1301 may also serve as the base.

The frame 1301 and the display unit 1302 may be curved. The radius of curvature thereof may be 5000 mm or more and 6000 mm or less.

FIG. 4B is a schematic diagram illustrating another example of the display apparatus of the present embodiment. A display apparatus 1310 illustrated in FIG. 4B is bendable, in other words, a foldable display apparatus. The display apparatus 1310 includes a first display unit 1311, a second display unit 1312, a casing 1313, and an inflection point 1314. The first display unit 1311 and the second display unit 1312 may each include a light emitting device of the present embodiment. The first display unit 1311 and the second display unit 1312 may constitute one seamless display apparatus. The first display unit 1311 and the second display unit 1312 can be separated at the inflection point. The first display unit 1311 and the second display unit 1312 may display different images, or may together display one image.

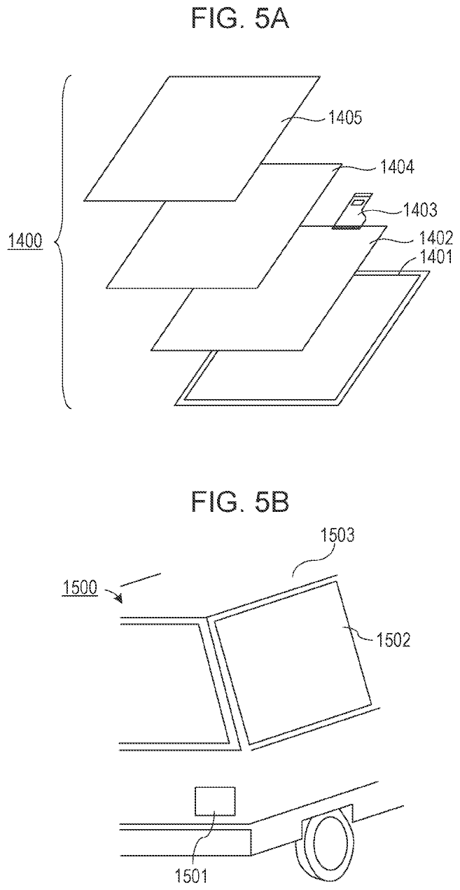

FIG. 5A is a schematic diagram illustrating one example of a lighting apparatus according to an embodiment. A lighting apparatus 1400 includes a casing 1401, a light source 1402, a circuit substrate 1403, an optical filter 1404, and a light diffusing unit 1405. The light source 1402 includes an organic light emitting element of the present embodiment. The optical filter 1404 may be a filter that improves the color rendering properties of the light source. The light diffusing unit 1405 can effectively diffuse light from the light source 1402, such as for lighting up, and can deliver the light to a wide range. The optical filter 1404 and the light diffusing unit 1405 may be disposed on the light emitting side of the lighting. If necessary, a cover may be provided on the outermost side.

The lighting apparatus is, for example, an apparatus that illuminates the room. The lighting apparatus may emit light that is white, neutral white, or any color from blue to red. The lighting apparatus may include a light modulating circuit that modulates these types of light. The lighting apparatus includes an organic light emitting element of the present embodiment and a power supply circuit connected to the organic light emitting element. The power supply circuit is a circuit that converts AC voltage into DC voltage. White is a color that has a color temperature of 4200 K and the neutral white is a color that has a color temperature of 5000 K. The lighting apparatus may include a color filter.

The lighting apparatus of the present embodiment may include a heat releasing unit. The heat releasing unit is a unit that releases the heat inside the apparatus to the outside of the apparatus, and examples thereof include metals having a high specific heat, and liquid silicone.

FIG. 5B is a schematic diagram of an automobile which is one example of a moving body according to an embodiment. The automobile includes a tail lamp, which is one example of a lighting unit. An automobile 1500 includes a tail lamp 1501 and may lit the tail lamp upon braking operation or the like.

The tail lamp 1501 includes an organic light emitting element of the present embodiment. The tail lamp may also include a protection member that protects the organic light emitting element. The protection member may be composed of any material that has a sufficiently high strength and is transparent, and can be composed of polycarbonate or the like.

The polycarbonate may be mixed with a furandicarboxylic acid derivative, an acrylonitrile derivative, or the like.

The automobile 1500 may include a car body 1503 and a window 1502 attached to the car body 1503. The window may be a transparent display if not a window for checking the front and rear sides of the automobile. This transparent display may include an organic light emitting element according to the present embodiment. In such a case, the materials constituting the electrodes, etc., of the organic light emitting element are transparent.

The moving body according to the present embodiment may be a ship, an airplane, a drone, or the like. The moving body includes a body and a lighting unit attached to the body. The lighting unit emits light to indicate the position of the body. The lighting unit includes an organic light emitting element of the present embodiment.

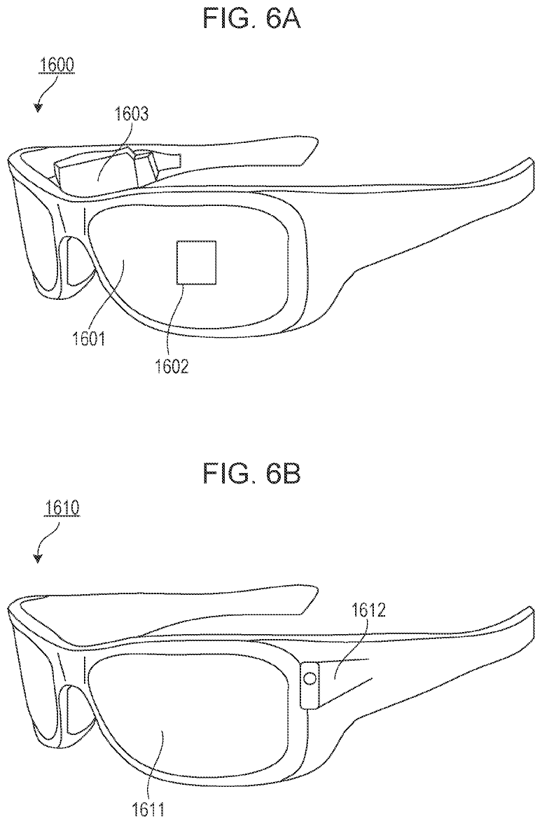

Referring now to FIGS. 6A and 6B, examples of applications of the display devices of the aforementioned embodiments are described. The display devices can be applied to wearable device systems such as smart glasses, HMD, and smart contact lenses. An imaging display apparatus used in such application examples includes an imaging device capable of converting visible light into electricity, and a display device capable of emitting visible light.

FIG. 6A illustrates glasses 1600 (smart glasses) according to one application example. An imaging device 1602 such as a CMOS sensor or SPAD is disposed on a front side of a lens 1601 of the glasses 1600. The display device according to any of the embodiments described above is disposed on a rear side of the lens 1601.

The glasses 1600 further include a controller 1603. The controller 1603 functions as a power supply that supplies power to the imaging device 1602 and the display device of the embodiment. The controller 1603 also controls the operation of the imaging device 1602 and the display device. An optical system for focusing light onto the imaging device 1602 is formed in the lens 1601.

FIG. 6B illustrates glasses 1610 (smart glasses) according to one application example. The glasses 1610 include a controller 1612, and the controller 1612 includes an imaging device that corresponds to the imaging device 1602 illustrated in FIG. 6A, and a display device. In a lens 1611, an optical system for projecting light emitted from the display device and the imaging device in the controller 1612 is formed, and images are projected onto the lens 1611. The controller 1612 functions as a power supply that supplies power to the imaging device and the display device, and also controls the operation of the imaging device and the display device. The controller may include a line-of-sight detecting unit that detects the line of sight of a wearer. The line of sight may be detected by using infrared radiation. The infrared radiation emitting unit emits infrared radiation toward an eyeball of a user gazing the displayed image. A captured image of the eyeball is obtained when the imaging unit having a light receiving element detects reflection of the emitted infrared radiation from the eyeball. The degradation of the image quality is decreased by providing a unit for reducing light from the infrared radiation emitting unit to the display unit in a plan view.

The line of sight of the user with respect to the displayed image is detected from the captured image of the eyeball obtained by infrared imaging. Any known technique can be applied to the line-of-sight detection using the captured image of the eyeball. For example, a line-of-sight detection method based on a Purkinje image formed by reflection of the irradiated light at the cornea can be employed.

More specifically, a line-of-sight detection process based on the pupil-corneal reflection method is performed. The line of sight of the user is detected by calculating the eye vector that indicates the direction (rotation angle) of the eyeball on the basis of the image of the pupil and the Purkinje image included in the captured image of the eyeball by using the pupil-corneal reflection method.

The display device of the present embodiment may include an imaging device that includes a light receiving element, and may control the display image on the display device on the basis of the line-of-sight information of the user from the imaging device.

Specifically, in the display device, a first view region that the user gazes and a second view region other than the first view region are determined on the basis of the line-of-sight information. The first view region and the second view region may be determined by the controller in the display device, or may be determined by an external controller and received. In the display region of the display device, the display resolution of the first view region may be controlled to be higher than the display resolution of the second view region. In other words, the resolution of the second view region may be lower than that of the first view region.

Furthermore, the display region has a first display region and a second display region different from the first display region, and a region having a higher priority is determined from the first display region and the second display region on the basis of the line-of-sight information. The first display region and the second display region may be determined by the controller in the display device, or may be determined by an external controller and received. The resolution of the region with higher priority may be controlled to be higher than the resolution of the region other than the region with higher priority. In other words, the resolution of a region having relatively low priority may be decreased.

An AI may be used to determine the first view region or the region with high priority. The AI may be a model configurated to estimate the angle of the line of sight and the distance to the object at the end of the line of sight from the image of the eyeball by using, as teaching data, the image of the eyeball and the direction in which the eyeball in the image was actually gazing. The AI program may be included in the display device, the imaging device, or an external device. When an external device includes the AI program, the data is transmitted to the display device via communication.

When the display is controlled on the basis of the visual recognition, smart glasses that further include an imaging device that captures the images of the outside can be implemented. The smart glasses can display the captured outside information in real time.

As described heretofore, by using devices that use the organic light emitting element of the present embodiment, a display with excellent image quality and stable for a long period of time can be achieved.

### EXAMPLES

The present disclosure will now be described more specifically through Examples that do not limit the present disclosure.

### Example 1

An example compound A-13 was synthesized through the following reaction scheme.

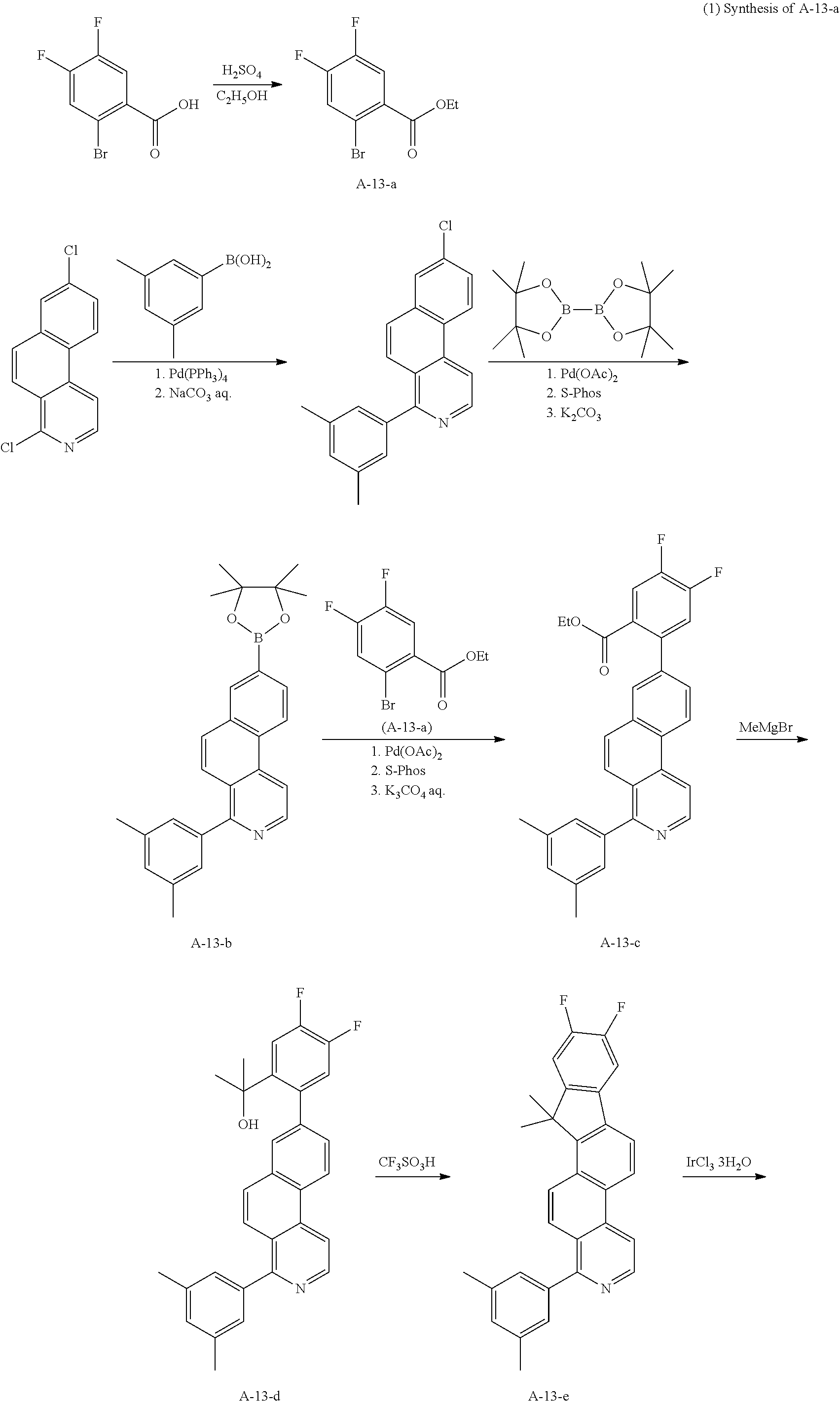

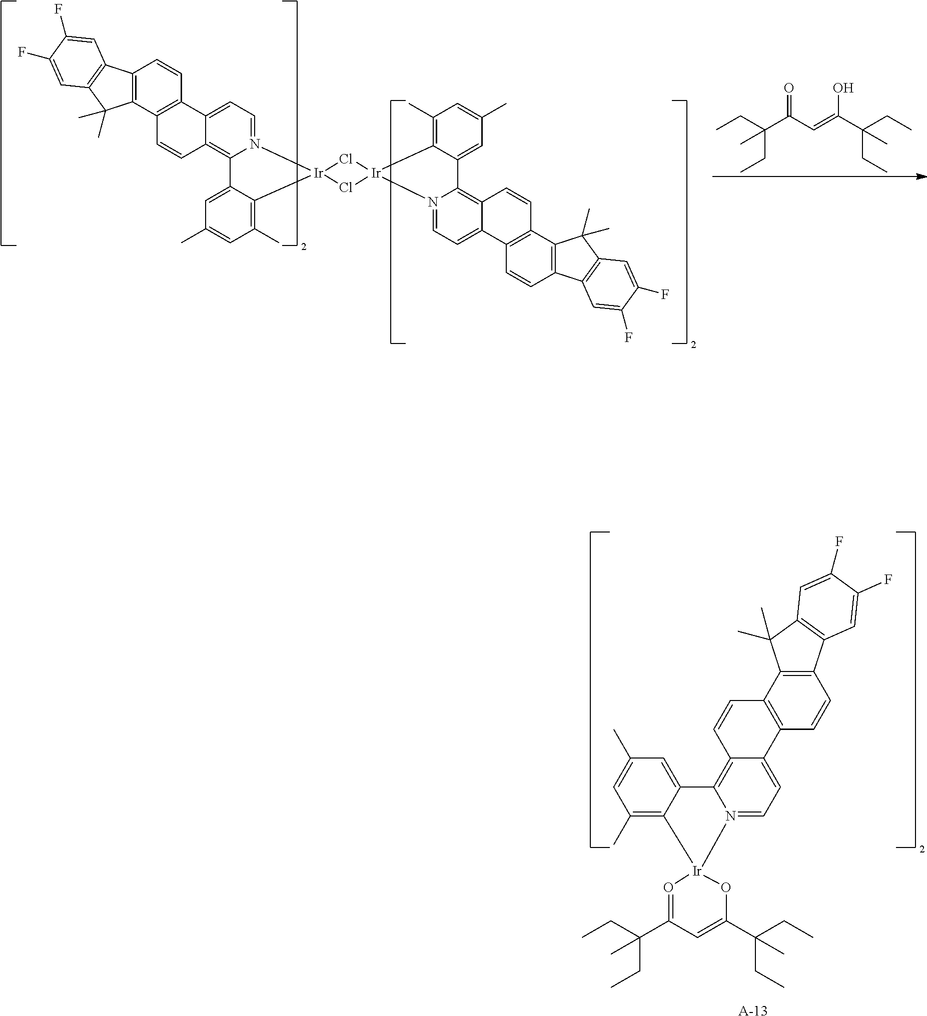

In a nitrogen atmosphere, 10.00 g of 2-bromo-4,5-diflulorobenzoic acid, 10.00 g of sulfuric acid, and 500 mL of ethanol were added to a flask. The resulting solution was heated to 90° C. and stirred for 8 hours. Upon completion of the reaction, ethyl acetate and water were added to extract an organic layer. After condensation, separation and purification were performed by silica gel column chromatography (eluent: toluene) and yielded 8.73 g of an intermediate A-13-a.

### (2) Synthesis of A-13-b

In a nitrogen atmosphere, 20.00 g of 4,8-dichlorobenzo[f]isoquinoline, 12.35 g of 3,5-dimethylphenylboronic acid, 0.86 g of tetrakistriphenylphosphine palladium, 15.84 g of sodium carbonate, 160 mL of toluene, 50 mL of ethanol, and 120 mL of ion exchange water were added to a flask. The resulting solution was heated to 90° C. and stirred for 3 hours. Upon completion of the reaction, toluene and water were added to extract an organic layer. After condensation, toluene and silica gel were added thereto, the resulting mixture was stirred and filtered, and the obtained solution was condensed and washed with methanol.

To a flask, 8.86 g of this methanol-washed solution, 12.74 g of bis(pinacolato)diboron, 0.09 g of palladium acetate, 0.34 g of 2-dicyclohexylphosphino-2′,6′-dimethoxybiphenyl (S-Phos), 16.42 g of potassium acetate, and 180 mL of 1,4-dioxane were added in a nitrogen atmosphere. The resulting solution was heated to 100° C. and stirred for 4 hours. Upon completion of the reaction, toluene and water were added to extract an organic layer, and the organic layer was condensed. The obtained crude was washed with methanol to obtain 10.10 g of an intermediate A-13-b.

### (3) Synthesis of A-13-c

In a nitrogen atmosphere, 3.31 g of the intermediate A-13-a, 5.10 g of the intermediate A-13-b, 0.04 g of palladium acetate, 0.21 g of S-Phos, 10.60 g of potassium phosphate, 90 mL of 1,4-dioxane, and 15 mL of ion exchange water were added to a flask. The resulting solution was heated to 100° C. and stirred for 10 hours. Upon completion of the reaction, toluene and water were added to extract an organic layer, and the organic layer was condensed. After the condensation, separation and purification were performed by silica gel column chromatography (eluent: toluene/ethyl acetate) and yielded 4.14 g of an intermediate A-13-c.

### (4) Synthesis of A-13-d

In a nitrogen atmosphere, 1.80 g of the intermediate A-13-c and 46 mL of super-dehydrated THF were added to a flask. This solution was cooled to 5° C., and a methylmagnesium bromide THF solution (1.04 M) was added thereto dropwise. After the dropwise addition, stirring was performed for 4 hours under ice cooling, and 22 mL of an aqueous solution of 2.2 g of ammonium chloride was added thereto to terminate the reaction. Subsequently, toluene and water were added, the organic layer was extracted and condensed, and then separation and purification were performed by silica gel column chromatography (eluent: toluene/ethyl acetate) and yielded 1.34 g of an intermediate A-13-d.

### (5) Synthesis of A-13-e

In a nitrogen atmosphere, 1.73 mL of trifluoromethanesulfonic acid and 18 mL of methylene chloride were added to a flask. The resulting solution was ice-cooled, and the intermediate A-13-d (1.21 g) dissolved in 6 mL of dichloromethane was added thereto dropwise. After stirring for 3 hours, the reaction solution was neutralized with water under ice cooling and then with an aqueous sodium hydroxide solution, dichloromethane was added thereto, and the organic layer was extracted and condensed. The obtained solid was washed with methanol to obtain 0.89 g of an intermediate A-13-e.

### (6) Synthesis of Example Compound A-13

In a nitrogen atmosphere, 0.60 g of the intermediate A-13-e, 0.24 g of a iridium chloride trihydrate, 12 mL of 2-ethoxyethanol, and 4 mL of pure water were added to a flask. The resulting solution was heated to 120° C. and stirred for 23 hours. Thereto, water was added, the deposited solid was filtered, and the solid on the paper filter was washed with toluene. To a flask, 0.37 g of this toluene-washed solid, 0.21 g of 3,7-diethyl-3,7-dimethyl-4,6-nonanedione, 6.1 mL of 2-ethoxyethanol, and 0.10 g of sodium carbonate were added. The resulting solution was heated to 120° C. and stirred for 2 hours in a nitrogen atmosphere, and then the solid was filtered. The obtained filtered solid was washed with methanol and water to obtain 0.37 g of an example compound A-13.

The results of the NMR measurement confirmed the presence of example compound A-13. The measurement results of the NMR spectrum are as follows.

1H-NMR (deuterated chloroform) δ (ppm): 8.95 (d, 2H), 8.73 (d, 2H), 8.45 (d, 2H), 8.33 (d, 2H), 7.98-7.96 (m, 6H), 7.65-7.61 (m, 2H), 7.38-7.33 (m, 2H), 6.59 (s, 2H), 5.12 (s, 1H), 2.38 (s, 6H), 1.85 (dd, 12H), 1.44 (s, 6H), 1.38-1.29 (m, 2H), 1.25-1.18 (m, 2H), 1.06-0.89 (m, 4H), 0.68 (s, 6H), 0.21-0.17 (m, 6H), 0.07-0.03 (m, 6H).

### Example 2

Example compound A-10 was synthesized through the following reaction scheme.

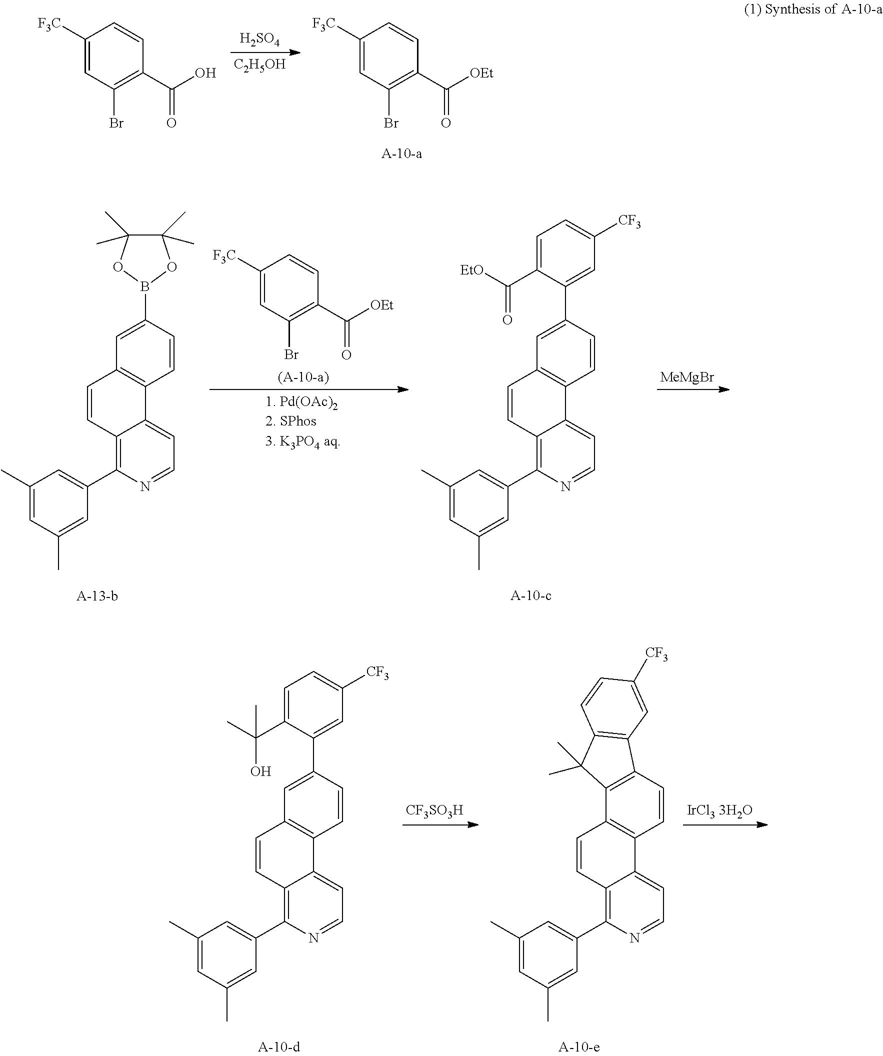

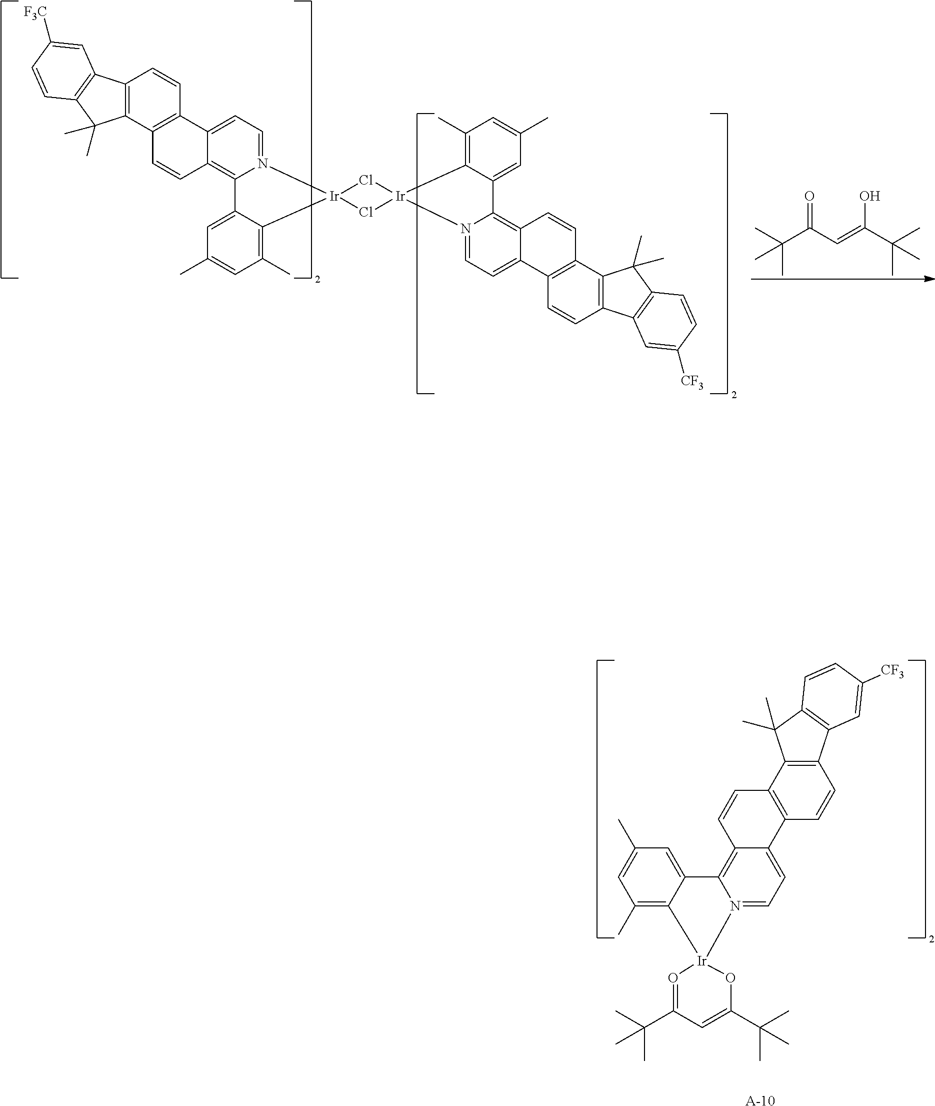

By the same synthesis method as that for the intermediate A-13-a, 7.51 g of an intermediate A-10-a was obtained except that 7.00 g of 2-bromo-4-(trifluoromethyl)benzoic acid was used instead of 2-bromo-4,5-difluorobenzoic acid in (1) of Example 1.

### (2) Synthesis of A-10-c

By the same synthesis method as that for the intermediate A-13-c, 4.72 g of an intermediate A-10-c was obtained except that 3.51 g of the intermediate A-10-a was used instead of the intermediate A-13-a in (3) of Example 1.

### (3) Synthesis of A-10-d

By the same synthesis method as that for the intermediate A-13-d, 2.08 g of an intermediate A-10-d was obtained except that 3.07 g of the intermediate A-10-c was used instead of the intermediate A-13-c in (4) of Example 1.

### (4) Synthesis of A-10-e

By the same synthesis method as that for the intermediate A-13-e, 2.08 g of an intermediate A-10-e was obtained except that 2.08 g of the intermediate A-10-d was used instead of the intermediate A-13-d in (5) of Example 1.

### (5) Synthesis of Example Compound A-10

By the same synthesis method as for the example compound A-13, 0.30 g of an example compound A-10 was obtained except that 1.00 g of the intermediate A-10-e was used instead of intermediate A-13-e and dipivaloylmethane was used instead of 3,7-diethyl-3,7-dimethyl-4,6-nonanedione in (6) in Example 1.

The results of the NMR measurement confirmed the presence of example compound A-10. The measurement results of the NMR spectrum are as follows.

1H-NMR (deuterated chloroform) δ (ppm): 8.94 (d, 2H), 8.77 (d, 2H), 8.39 (d, 2H), 8.35 (d, 2H), 8.13-8.11 (m, 4H), 8.04 (d, 2H), 8.02 (s, 2H), 6.68 (s, 4H), 6.58 (s, 2H), 5.17 (s, 1H), 2.37 (s, 6H), 1.89 (d, 12H), 1.44 (s, 6H), 0.68 (s, 2H).

### Example 3

An organic light emitting element in which an anode/hole injection layer/hole transport layer/electron blocking layer/light emission layer/hole blocking layer/electron transport layer/cathode structure was sequentially formed on a substrate was produced by the method described below using the example compound A-13 in Example 1 as the guest compound in the host molecule of the light emission layer.

A glass substrate on which a 100 nm-thick ITO film serving as an anode was formed by a sputtering method was used as a transparent conductive supporting substrate (ITO substrate). Organic compound layers and electrode layers indicated below were continuously vacuum-deposited on this ITO substrate under resistance heating in a 10⁻⁵ Pa vacuum chamber. Here, the layers were produced so that the electrode area was 3 mm². The figure inside the parentheses below indicate the film thickness.
Hole injection layer (10 nm) HT16
Hole transport layer (30 nm)
Electron blocking (EB) layer (10 nm)
Light emission layer (30 nm): host material+guest material (example compound A-13 (4 mass %))
Hole blocking (HB) layer (20 nm)
Electron transport layer (20 nm)
Metal electrode layer 1 (1 nm): Liq
Metal electrode layer 2 (100 nm): Al

Next, to prevent deterioration of the organic light emitting element by moisture adsorption, a protective glass plate was placed over the resulting product and sealed with an acrylic resin adhesive. As a result, an organic light emitting element was obtained. The obtained organic light emitting element was measured for its IVL (current-voltage-luminance) by using the ITO electrode and the anode and the Al electrode as the cathode. The external quantum efficiency and the lifetime of the organic light emitting element are indicated in Table 2. Here, the external quantum efficiency is a value at 5 mA/cm², and the lifetime is the endurance time (LT95) taken for the luminance to reach 95% of the initial luminance, 100%, of the organic light emitting element at 20 mA/cm² as the organic light emitting element is continuously driven at 20 mA/cm². Furthermore, the external quantum efficiency and the lifetime in Table 2 are each a relative value that assumes that the corresponding value of Comparative Example 1 (comparative compound Ref-1) is 100.

### Example 4

An organic light emitting element was produced as in Example 3 except that the guest material was changed to the example compound A-10 synthesized in Example 2. The obtained element was measured to determine the external quantum efficiency and the lifetime as in Example 3. The results are indicated in Table 2.

### Comparative Example 1

An organic light emitting element of Comparative Example 1 was produced as in Example 3 except that the guest material was changed to a comparative compound Ref-1 indicated below. Ref-1 is a compound that is different from the organic metal complex of the present embodiment in that another aromatic ring bonded to the BIQ ring via a five-membered ring structure is absent.

### Comparative Example 2

An organic light emitting element of Comparative Example 2 was produced as in Example 3 except that the guest material was changed to a comparative compound Ref-2 indicated below. Ref-2 is a compound that is different from the example compound A-13 of the present embodiment in that another aromatic ring is bonded to the BIQ ring via a single bond instead of a five-membered ring structure.

### Comparative Example 3

An organic light emitting element of Comparative Example 3 was produced as in Example 3 except that the guest material was changed to a comparative compound Ref-3 indicated below. Ref-3 is a compound that is different from the example compound A-10 of the present embodiment in that another aromatic ring is bonded to the BIQ ring via a single bond instead of a five-membered ring structure.

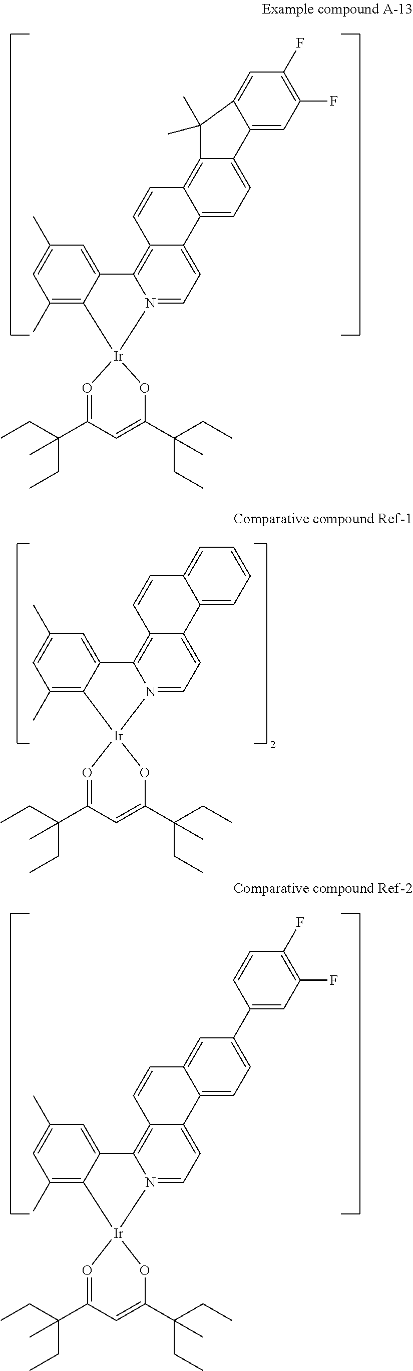

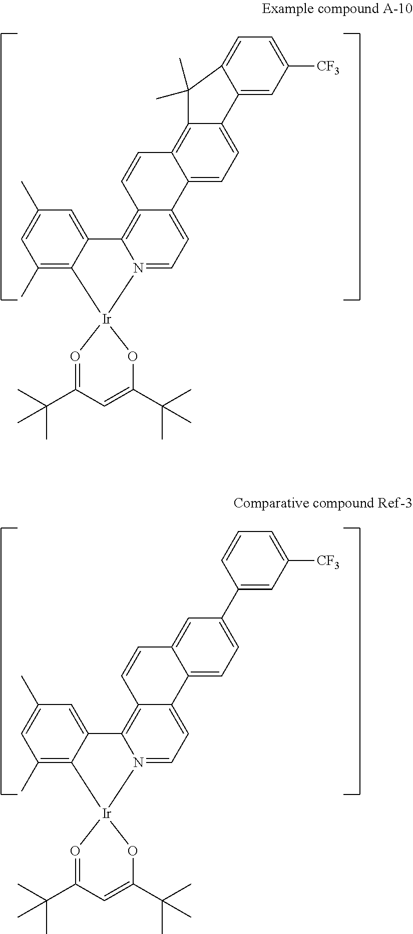

TABLE 2

| | | External quantum | Lifetime |
|---|---|---|---|
| | Guest compound | efficiency | (LT95) |
| | of light | (relative | (relative |
| | emission layer | value (%)) | value (%)) |
| Comparative | Ref-1 | 100 | 100 |
| Example 1 | | | |
| Example 3 | Example | 118 | 121 |
| | compound A-13 | | |
| Example 4 | Example | 124 | 137 |
| | compound A-10 | | |
| Comparative | Ref-2 | 111 | 48 |
| Example 2 | | | |
| Comparative | Ref-3 | 122 | 51 |
| Example 3 | | | |

Compared to the organic metal complex of Comparative Example 1, the organic metal complexes of Examples 3 and 4 and Comparative Examples 2 and 3 have a phenyl group bonded to the BIQ ring and the conjugation is expanded in a direction away from the iridium atom; thus, the transition dipole moment is increased, and all exhibit high external quantum efficiency. However, the organic metal complexes of Comparative Examples 2 and 3 only have a single bond that links the BIQ ring to the phenyl group, and thus the molecular stability is lacking and the element lifetime is short. In contrast, in Examples 3 and 4 that used the example compounds A-13 and A-10 of the present embodiment, the element lifetime is sufficiently long.

As described above, according to the organic metal complex of the present embodiment, the organic light emitting element can achieve both high light emission quantum efficiency and long element lifetime.

The present disclosure can provide an organic metal complex that achieves both high light emitting efficiency and long lifetime.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-189150 filed Nov. 28, 2022, and Japanese Patent Application No. 2023-114990 filed Jul. 13, 2023, which are hereby incorporated by reference herein in their entirety.

What is claimed is:

1. An organic metal complex represented by formula (1) below:
MLₚL¹ₘL²ₙ (1)
in formula (1), L, L¹, and L² represent different ligands,
M is Ir, Rh, Pt, or Pd,
p is an integer of 1 to 3,
m is an integer of 0 to 2,
n is an integer of 0 to 2,
when M is Ir or Rh, p+m+n=3, and
when M is Pt or Pd, p+m+n=2,
MLₚ is represented by formula (2) below: 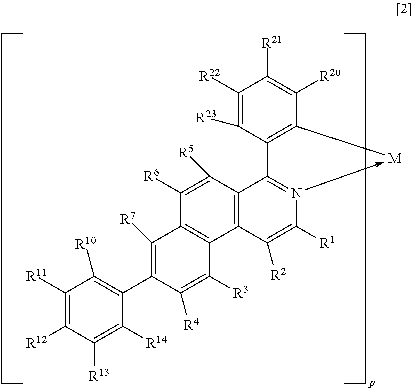
in formula (2), R¹ to R⁷, R¹⁰ to R¹⁴, R²⁰ to R²³ are each independently selected from the group consisting of a hydrogen atom, a deuterium atom, a halogen atom, a substituted or unsubstituted alkyl group, a substituted or unsubstituted alkoxy group, a substituted or unsubstituted aryl group, a substituted or unsubstituted aryloxy group, a substituted or unsubstituted heterocyclic group, a substituted or unsubstituted aralkyl group, a substituted or unsubstituted amino group, a silyl group, and a cyano group,
R⁴ and R¹⁴ and/or R⁷ and R¹⁰ are bonded together to form a five-membered ring structure,
any of R¹ to R⁷, R¹⁰ to R¹⁴, and R²⁰ to R²³ may form a ring structure by bonding with an adjacent substituent,
ML¹ₘ and ML²ₙ are respectively represented by formulae (3) and (4): 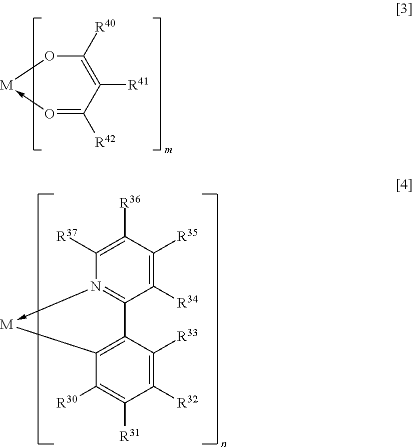
in formulae (3) and (4), R³⁰ to R³⁷ and R⁴⁰ to R⁴² are each independently selected from the group consisting of a hydrogen atom, a deuterium atom, a halogen atom, a substituted or unsubstituted alkyl group, a substituted or unsubstituted alkoxy group, a substituted or unsubstituted aralkyl group, a substituted or unsubstituted amino group, a substituted or unsubstituted aryl group, and a substituted or unsubstituted heterocyclic group.

2. The organic metal complex according to claim 1, wherein MLₚ in the organic metal complex is represented by formula (5): 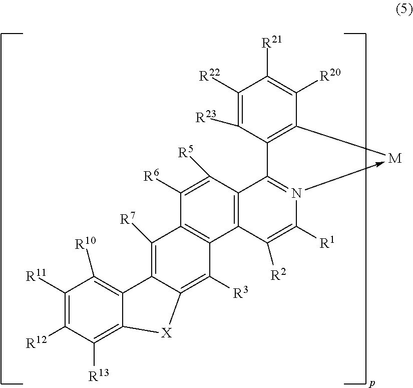
in formula (5), X is selected from CRR′, C═O, SiRR′, O, S, SO₂, and NR, where R and R′ are each independently selected from the group consisting of a substituted or unsubstituted alkyl group, a substituted or unsubstituted aryl group, and a halogen atom.

3. The organic metal complex according to claim 1, wherein MLₚ in the organic metal complex is represented by formula (6): 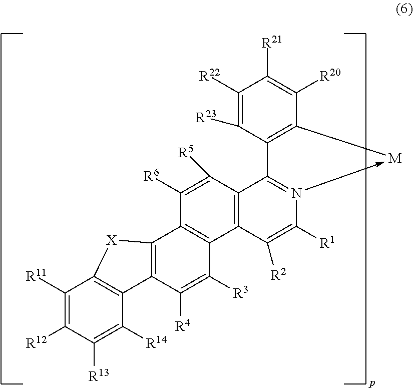
in formula (6), X is selected from CRR′, C═O, SiRR′, O, S, SO₂, and NR, where R and R′ are each independently selected from the group consisting of a substituted or unsubstituted alkyl group, a substituted or unsubstituted aryl group, and a halogen atom.

4. The organic metal complex according to claim 1, wherein MLₚ in the organic metal complex is represented by formula (7): 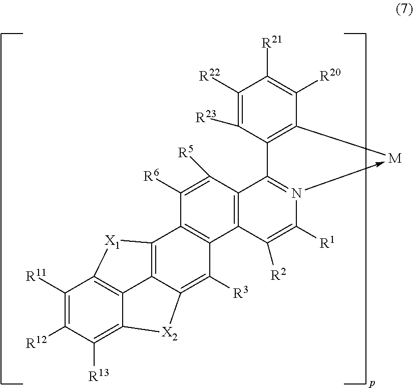
in formula (7), X₁ and X₂ are each independently selected from CRR′, C═O, SiRR′, O, S, SO₂, and NR, where R and R′ are each independently selected from the group consisting of a substituted or unsubstituted alkyl group, a substituted or unsubstituted aryl group, and a halogen atom.

5. The organic metal complex according to claim 1, wherein
in formula (2), the ring structure is formed by R⁴ and R¹⁴ and/or by R⁷ and R¹⁰ via one of CRR′ and C═O, where R and R′ are each independently selected from the group consisting of a substituted or unsubstituted alkyl group, a substituted or unsubstituted aryl group, and a halogen atom, and
at least one of R¹⁰ to R¹⁴ that are not involved in forming the ring structure is an electron-withdrawing substituent having a para-Hammett constant op higher than or equal to 0.2.

6. The organic metal complex according to claim 5, wherein the electron-withdrawing substituent is selected from —CF₃, —CN, —COCH₃, and —F.

7. The organic metal complex according to claim 1, wherein, in formula (2), the ring structure is formed by R⁴ and R¹⁴ and/or by R⁷ and R¹⁰ via one of C(CH₃)₂ and S.

8. A luminescent ink composition comprising:
the organic metal complex according to claim 1; and
a solvent.

9. An organic light emitting element comprising:
a first electrode;
a second electrode; and
an organic compound layer disposed between the first electrode and the second electrode,
wherein the organic compound layer contains the organic metal complex according to claim 1.

10. The organic light emitting element according to claim 9,
wherein the organic compound layer includes a light emission layer, and
the light emission layer includes the organic metal complex and a first organic compound that has a lowest excited singlet energy and a lowest excited triplet energy larger than those of the organic metal complex.

11. The organic light emitting element according to claim 10, wherein the light emission layer includes a second organic compound different from the first organic compound, and the second organic compound has a lowest excited triplet energy smaller than the lowest excited triplet energy of the first organic compound but larger than the lowest excited triplet energy of the organic metal complex.

12. A display device comprising a plurality of pixels,
wherein at least one of the plurality of pixels includes the organic light emitting element according to claim 9, and a transistor connected to the organic light emitting element.

13. An imaging device comprising:
an optical unit that includes a plurality of lenses;
an imaging element that receives light that has passed through the optical unit; and
a display unit that displays an image captured by the imaging element,
wherein the display unit includes the organic light emitting element according to claim 9.

14. Electronic equipment comprising:
a display unit that includes the organic light emitting element according to claim 9;
a casing in which the display unit is disposed; and
a communication unit that is disposed in the casing to perform external communication.

15. A lighting apparatus comprising:
a light source that includes the organic light emitting element according to claim 9; and
a light diffusing unit or an optical filter that transmits light emitted from the light source.

16. A moving body comprising:
a lighting unit that includes the organic light emitting element according to claim 9; and
a body in which the lighting unit is provided.

17. An image forming apparatus comprising:
a photosensitive body; and
an exposure light source that exposes the photosensitive body with light,
wherein the exposure light source includes the organic light emitting element according to claim 9.
